(19) United States
(12) Patent Application Publication
(10) Pub. No.: US 2012/0185749 A1
(43) Pub. Date: Jul. 19, 2012

(54) STORAGE APPARATUS AND RESPONSE TIME CONTROL METHOD

(75) Inventors: Gosuke Okada, Fujisawa (JP); Tomohisa Ogasawara, Odawara (JP); Yukiyoshi Takamura, Kamakura (JP)

(73) Assignee: Hitachi, Ltd.

(21) Appl. No.: 13/056,055

(22) PCT Filed: Jan. 14, 2011
(86) PCT No.: PCT/JP2011/000167

§ 371 Date: Jan. 26, 2011

(51) Int. Cl. H03M 13/09; G06F 11/08

(52) U.S. Cl. 714/758; 714/E11.03

(57) ABSTRACT

A storage apparatus and response time control method capable of preventing response performance deterioration effectively are suggested. Since a response time control unit which delays a response of a corresponding storage device to a command and transfers it to a controller for a storage apparatus is located between the controller and part of or all storage devices in order to equalize response time for the plurality of storage devices to respond to a command issued from the controller, it is possible to equalize the response time of the plurality of storage devices and thereby effectively prevent deterioration of the response performance of the storage apparatus.

### TECHNICAL FIELD

The present invention relates to a storage apparatus and a response time control method and is suited for use in, for example, a storage apparatus in which a RAID (Redundant Array of Independent Disks) function is installed.

### BACKGROUND ART

Conventionally, with this type of storage apparatus, one ECC (Error Check and Correction) group is formed of a plurality of storage devices (e.g. hard disk devices) and a logical volume is defined in a storage area provided by each of the storage devices constituting the one ECC group. Then, data from a host computer is read from, or written to, this logical volume.

It should be noted that the Patent Literature 1 mentioned below discloses that a drive mode of a multi-mode hard disk is controlled in accordance with an amount of input data stored in a buffer memory.

### CITATION LIST

### Patent Literature

PTL 1: Japanese Patent Application Laid-Open (Kokai) Publication No. H11-306679

### SUMMARY OF INVENTION

### Technical Problem

Meanwhile, when reading data from, or writing data to, a storage area (logical volume) provided by an ECC group, a storage apparatus in which such a RAID function is installed divides the data and concurrently reads it from, or writes it to, each storage device constituting the ECC group. Therefore, if the performance of each storage device constituting the ECC group is individually different, there is a problem of response performance degradation of the entire ECC group due to an impact of a storage device with the lowest response performance. Therefore, with this type of storage apparatus, an ECC group is normally constituted from a plurality of storage devices with the same response performance.

However, it may sometimes become necessary to replace part of the plurality of storage devices constituting an ECC group due to a failure, for maintenance, or for other reasons. In this case, it might be possible that the manufacturing of storage devices with the same response performance as other storage devices constituting that ECC group (hereinafter referred to as the existing storage devices) has already been suspended; and in that case, it is necessary to use new storage devices.

In this case, the performance of new storage devices is normally higher than that of the existing storage devices. Then, if any storage devices whose performance is extremely high exist in the same ECC group, there is a problem in that commands cannot be fully processed in the existing storage devices whose response performance is low, so that system resources are occupied by the commands accumulated in a command queue, which results in degradation of the response performance of the entire system.

The present invention was devised in view of the circumstances described above and is intended to suggest a storage apparatus and response time control method capable of effectively preventing deterioration of the response performance.

### Solution to Problem

In order to solve the above-described problems, a storage apparatus according to the present invention includes: a plurality of storage devices; a controller for controlling data input to, or output from, the plurality of storage devices; and a response time control unit that is located between the controller and part of or all the storage devices and delays a response of a corresponding storage device to a command issued from the controller and transfers it to the controller in order to equalize response time for the plurality of storage devices to respond to the command.

Furthermore, a response time control method for a storage apparatus including a plurality of storage devices and a controller for controlling data input to, or output from, the plurality of storage devices is provided according to this invention, wherein a response time control unit that is located between the controller and part of or all the storage devices is provided in the storage apparatus. The response time control method includes: a first step executed by the response time control unit of transferring a command issued from the controller to a corresponding storage device; and a second step executed by the response time control unit of delaying a response from the corresponding storage device to the command and transferring it to the controller in order to equalize response time for the plurality of storage devices to respond to the command.

As a result, the storage apparatus and response time control method according to this invention makes it possible to equalize the response time for a plurality of multiple storage devices.

### ADVANTAGEOUS EFFECTS OF INVENTION

According to this invention, the deterioration of response performance of a storage apparatus can be prevented effectively.

### BRIEF DESCRIPTION OF DRAWINGS

FIG. 1 is a block diagram showing the entire configuration of a computer system according to Embodiments 1 to 6.

FIGS. 2(A) and (B) are conceptual diagrams explaining problems of the conventional technology.

FIG. 3 is a block diagram explaining conversion chips.

FIGS. 4(A) to (C) are conceptual diagrams explaining first response time control processing.

FIG. 5 is a sequential diagram explaining the first response time control processing.

FIGS. 6 (A) to (C) are conceptual diagrams explaining second response time control processing.

FIG. 7 is a sequential diagram explaining the second response time control processing.

FIGS. 8(A) to (C) are sequential diagrams explaining third response time control processing.

FIGS. 9(A) to (C) are sequential diagrams explaining the third response time control processing.

FIG. 10 is a flowchart showing a processing procedure of the third response time control processing.

FIGS. 11(A) to (D) are conceptual diagrams explaining sequential access, random access, and multi-thread access.

FIGS. 12(A) and (B) are conceptual diagrams explaining fourth response time control processing.

FIG. 13 is a conceptual diagram explaining a read response time management table.

FIG. 14 is a conceptual diagram explaining a write response time management table.

FIG. 15 is a flowchart showing a processing procedure of the fourth response time control processing.

FIG. 16 is a conceptual diagram explaining a method for judging the sequentiality of read/write positions according to according to this embodiment.

FIGS. 17(A) to (D) are conceptual diagrams explaining a method for judging the sequentiality of read/write positions according to this embodiment.

FIG. 18 is a conceptual diagram explaining a thread management basic table.

FIG. 19 is a conceptual diagram explaining the latest received command management table.

FIGS. 20(A) and (B) are conceptual diagrams explaining a specific example of an access pattern judgment method according to this embodiment.

FIGS. 21(A) to (C) are conceptual diagrams explaining a specific example of the access pattern judgment method according to this embodiment.

FIGS. 22(A) to (C) are conceptual diagrams explaining a specific example of the access pattern judgment method according to this embodiment.

FIGS. 23(A-1) to (D) are conceptual diagrams explaining a specific example of the access pattern judgment method according to this embodiment.

FIGS. 24(A) to (D) are conceptual diagrams explaining a specific example of the access pattern judgment method according to this embodiment.

FIGS. 25(A) to (D-2) are conceptual diagrams explaining a specific example of the access pattern judgment method according to this embodiment.

FIGS. 26(A) to (D) are conceptual diagrams explaining a specific example of the access pattern judgment method according to this embodiment.

FIGS. 27(A) to (C) are conceptual diagrams explaining a specific example of the access pattern judgment method according to this embodiment.

FIGS. 28(A) and (B) are conceptual diagrams explaining a specific example of the access pattern judgment method according to this embodiment.

FIGS. 29(A) and (B) are conceptual diagrams explaining a specific example of the access pattern judgment method according to this embodiment.

FIGS. 30(A) and (B) are conceptual diagrams explaining a specific example of the access pattern judgment method according to this embodiment.

FIGS. 31(A) and (B) are conceptual diagrams explaining a specific example of the access pattern judgment method according to this embodiment.

FIG. 32 is a flowchart illustrating a processing procedure of access pattern judgment processing.

FIG. 33 is a flowchart illustrating a processing procedure of fifth response time control processing.

FIG. 34 is a flowchart illustrating a processing procedure of sixth response time control processing.

### DESCRIPTION OF EMBODIMENTS

An embodiment of the present invention will be explained below with reference to the attached drawings.

(1) Embodiment 1

(1-1) Configuration of Computer System according to This Embodiment

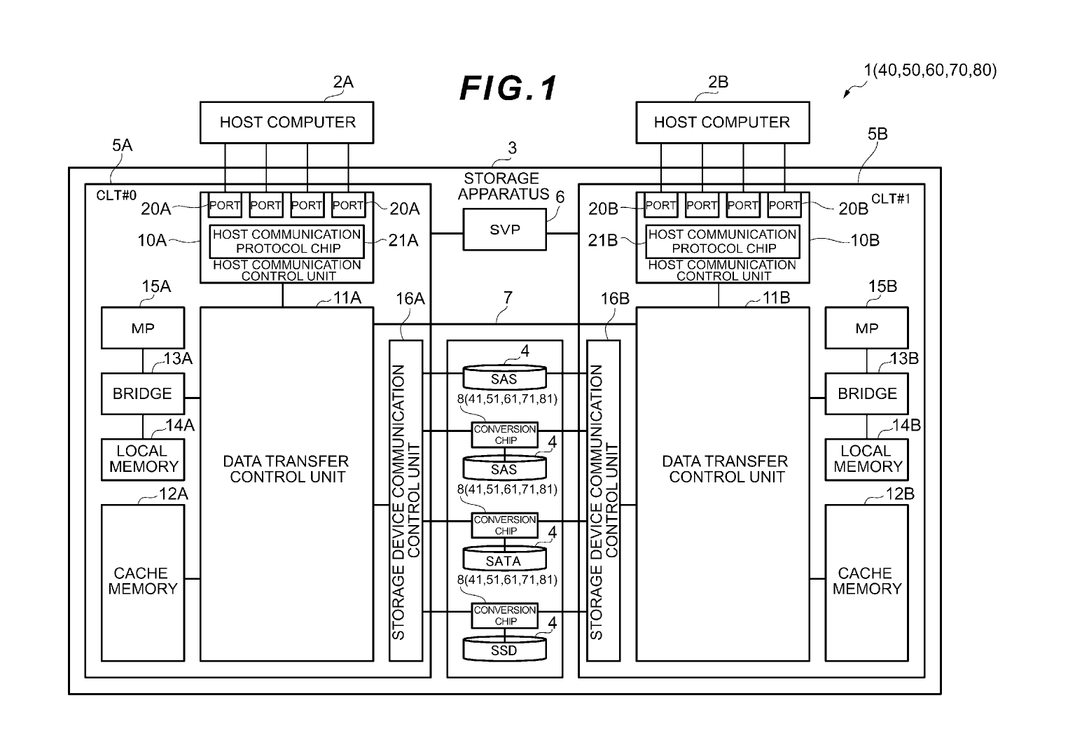

Referring to FIG. 1, the reference numeral 1 represents a computer system as a whole according to this embodiment. This computer system 1 includes host computers 2A, 2B and a storage apparatus 3.

The host computer 2A, 2B is a computer equipped with information processing resources such as a CPU (Central Processing Unit) and a memory. Specifically speaking, the host computer 2A, 2B is composed of, for example, a personal computer, a workstation, or a mainframe. The host computer 2A, 2B is provided with communication ports for accessing the storage apparatus 3 (e.g. LAN cards and ports provided in host bus adapters). The host computer 2A, 2B is designed so that it can send various types of commands to the storage apparatus 3 via these communication ports.

The storage apparatus 3 includes a plurality of storage devices 4, 0-system and 1-system controllers 5A, 5B, which are respectively connected to the different host computers 2A, 2B, and a management terminal 6.

The storage devices 4 are composed of hard disk devices such as SAS (Serial Attached SCSI) hard disk devices or SATA (Serial Advanced Technology Attachment) hard disk devices, or storage devices other than hard disk devices such as SSDs (Solid State Drives). One ECC group is constituted from one or more storage devices 4 and one or more logical volumes are defined in a storage area provided by each of the storage devices 4 constituting one ECC group. Data from the host computers 2A, 2B is stored in blocks of specified size (hereinafter referred to as the logical blocks) in these logical volumes.

A unique identifier (LUN: Logical Unit Number) is assigned to each logical volume. In a case of this embodiment, data input/output is performed by designating, as an address, a combination of this identifier and an identification number assigned to each logical block (LBA: Logical Block Address).

The controllers 5A, 5B are connected via an inter-controller connection path 7 so that they can communicate with each other. As the inter-controller connection path 7, for example, a bus in accordance with the PCI (Peripheral Component Interconnect—Express standard for achieving high-speed data communication by which a data transfer amount per lane (to a maximum of 8 lanes) one-way communication is 2.5 [Gbit/sec] is applied. Data and various types of information are sent and received between the 0-system and 1-system controllers 5A, 5B via this inter-controller connection path 7.

Each controller 5A, 5B has a function controlling data input to, and/or output from, the storage devices 4 in response to requests from the host computers 2A, 2B connected to their local controllers respectively, and includes, for example, a host communication control unit 10A, 10B, a data transfer control unit 11A, 11B, a cache memory 12A, 12B, a bridge 13A, 13B, a local memory 14A, 14B, a microprocessor 15A, 15B, and a storage device communication control unit 16A, 16B.

The host communication control unit 10A, 10B is an interface for controlling communication between the host computers 2A, 2B, and includes a plurality of communication ports 20A, 20B and a host communication protocol chip 21A, 21B.

The communication port 20A, 20B is used to connect the relevant controller 5A, 5B to the network and the host computer 2A, 2B, and a unique network address such as an IP (Internet Protocol) address or a WWN (World Wide Name) is assigned to it.

Furthermore, the host communication protocol chip 21A, 21B performs protocol control during communication between the host computers 2A, 2B. For this purpose, the host communication protocol chips 21A, 21B, which are suited for the communication protocol with the host computers 2A, 2B are used; for example, Fibre Channel conversion protocol chips are used in a case where the communication protocol between the host computers 2A, 2B is a Fibre Channel (FC) protocol, or iSCSI protocol chips are used in a case where the relevant communication protocol is an iSCSI (internet Small Computer System Interface) protocol.

Furthermore, the host communication protocol chip 21A, 21B has a multi-microprocessors function capable of communicating with a plurality of microprocessors. Accordingly, it is designed so that the host communication protocol chip 21A, 21B can communicate with both the microprocessor 15A in the 0-system controller 5A and the microprocessor 15B in the 1-system controller 5B as needed.

The data transfer control unit 11A, 11B has a function controlling data transfer between the 0-system and 1-system controllers 5A, 5B and data transfer between the respective components in the 0-system or 1-system controller 5A, 5B. The data transfer control unit 11A, 11B also has a function copying (multiple-writing) write data given from the host computer 2A, 2B to a specified cache memory 12A, 12B in accordance with an instruction from the microprocessor 15A, 15B for its own system. Specifically speaking, when the 0-system or 1-system microprocessor 15A, 15B stores data in its own cache memory 12A, 12B, it also writes this data to the cache memory 12A, 12B for the other system (double writing).

Furthermore, when information in one shared area of the local memory 14A or 14B is updated, the data transfer control units 11A, 11B also update information in the other shared area in the same way so that the information stored in the shared areas of the local memories 14A, 14B for its own system and the other system will be always the same.

The bridge 13A, 13B is a relay device for connecting the microprocessor 15A, 15B and the local memory 14A, 14B for its local system to the data transfer control unit 11A, 11B for its local system respectively; and extracts only the corresponding data from among data flowing through a bus which connects the host communication control unit 10A, 10B, the data transfer control unit 11A, 11B, the storage device communication control unit 16A, 16B, and the cache memory 12A, 12B, and transfers the extracted data to the microprocessor 15A, 15B and the local memory 14A, 14B.

Each microprocessor 15A, 15B has a function controlling the operation of the entire controller 5A, 5B for its local system. These microprocessors 15A, 15B perform processing such as data input/output control of logical volumes which are exclusively assigned to the microprocessors 15A, 15B in advance (hereinafter referred to as the associated logical volumes) in accordance with write commands and read commands stored in the local memories 14A, 14B, as described below.

Such assignment of the associated logical volumes to each microprocessor 15A, 15B can be dynamically changed depending on the load status of each microprocessor 15A, 15B and the reception of microprocessor-in-charge designating commands which designates a microprocessor in charge of each logical volume given from the host computers 2A, 2B. Furthermore, the assignment of the associated logical volumes to each microprocessor 15A, 15B can also be dynamically changed depending on whether a failure has occurred or not in, for example, a connection path between the controllers 5A, 5B and the host computers 2A, 2B, and a connection path between the controllers 5A, 5B and the storage devices 4.

The local memory 14A, 14B is used to not only store various types of control programs, but also temporarily retain various types of commands such as read commands and write commands given from the host computers 2A, 2B. The microprocessor 15A, 15B processes the read commands and the write commands stored in the local memory 14A, 14B in the order stored in the relevant local memory 14A, 14B.

The cache memory 12A, 12B is used mainly to temporarily store data transferred between the host computers 2A, 2B and the storage devices 4A to 4D, and between the 0-system and 1-system controllers 5A, 5B.

The storage device communication control unit 16A, 16B is an interface for controlling communication with each storage device 4. The storage device communication control unit 16A, 16B controls communication with the storage devices 4 in accordance with a communication protocol according to the SAS standard.

However, with the computer system 1 according to this embodiment, for, example, SATA hard disk devices or SSDs, other than SAS hard disk devices, may be sometimes used as the storage devices 4. Therefore, in the case of the computer system 1, conversion chips 8 integrated with the storage devices 4 are installed for the storage devices 4 which comply to the above-mentioned standard other than SAS standard.

The conversion chip 8 is an electronic component, in which, for example, a protocol conversion function similar to that of a shelf disclosed in Japanese Unexamined Patent Application Publication (Translation of PCT Application) No. 2006-517699 is installed, and which transfers various types of commands and data, which have been transferred from the storage device communication control unit 16A, 16B for the controller 5A, 5B in accordance with a communication protocol according to the SAS standard, to the relevant storage device 4, to which that conversion chip 8 is attached, in accordance with a communication protocol according to a standard to which that storage device 4 complies (such as the SATA standard, Fibre Channel standard, or SCSI standard). Furthermore, the conversion chip 8 transfers various types of commands and data, which have been transmitted from the storage devices 4, to the storage device communication control unit 16A, 16B for the controller 5A, 5B in accordance with a communication protocol according to the SAS standard. Incidentally, the configuration and other functions of the conversion chip 8 will be described later.

The management terminal 6 is a computer device used to maintain and manage the storage apparatus 3 and is composed of, for example, a laptop computer. The management terminal 6 is connected to each controller 5A, 5B, which monitors whether a failure has occurred or not in the storage apparatus 3; and if a failure occurs, the management terminal 6 executes processing for, for example, reporting the failure to an external management console (not shown in the drawing), having it display the failure, and giving a command to block the storage devices 4 in accordance with a command given from the management console as operated by an operator.

(1-2) Response Time Control Function

Next, a response time control function installed in the conversion chip 8 will be described.

As described above, an ECC group is normally constituted from a plurality of storage devices having the same response performance, but there are some cases where it becomes necessary to replace part of the storage devices due to a failure, for maintenance, or for other reasons. In this case, it might be possible that manufacture of the same type of storage devices as the existing storage devices constituting the ECC group has already been suspended; and in such a case, it is necessary to use new storage devices.

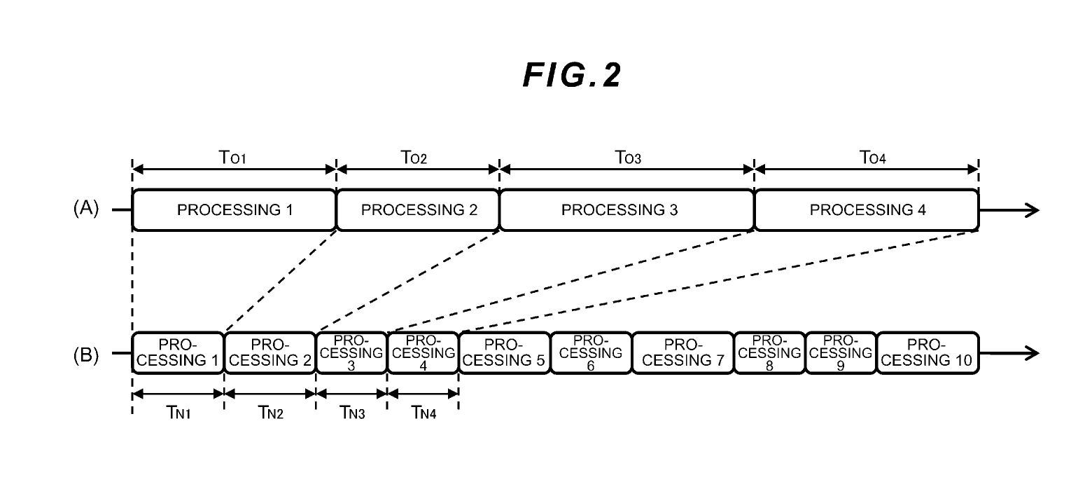

However, as shown in FIGS. 2(A) and (B), a processing speed of new storage devices is generally faster than a processing speed of the existing storage devices, and processing time T_{O1}, T_{O2}, and so on (FIG. 2 (B)) of the new storage devices with respect to individual processing is shorter than processing time T_{N1}, T_{N2}, and so on (FIG. 2 (A)) of the existing storage devices. Then, if any storage devices whose performance is extremely high exist in the same ECC group, there is a problem in that commands cannot be processed fully in the existing storage devices whose response performance is low and system resources are occupied by commands accumulated in a command queue, which results in degradation of the response performance of the entire system.

Therefore, in a case of the storage apparatus 3 according to this embodiment, the conversion chip 8 is equipped with a response time delay function delaying response time from the storage devices 4 to commands issued from the controller 5A, 5B. Then, if part of the storage devices 4 constituting the ECC group is to be replaced with new storage devices 4 in the case of this storage apparatus 3, the conversion chips 8 integrated with the new storage devices 4 are installed as shown in FIG. 1.

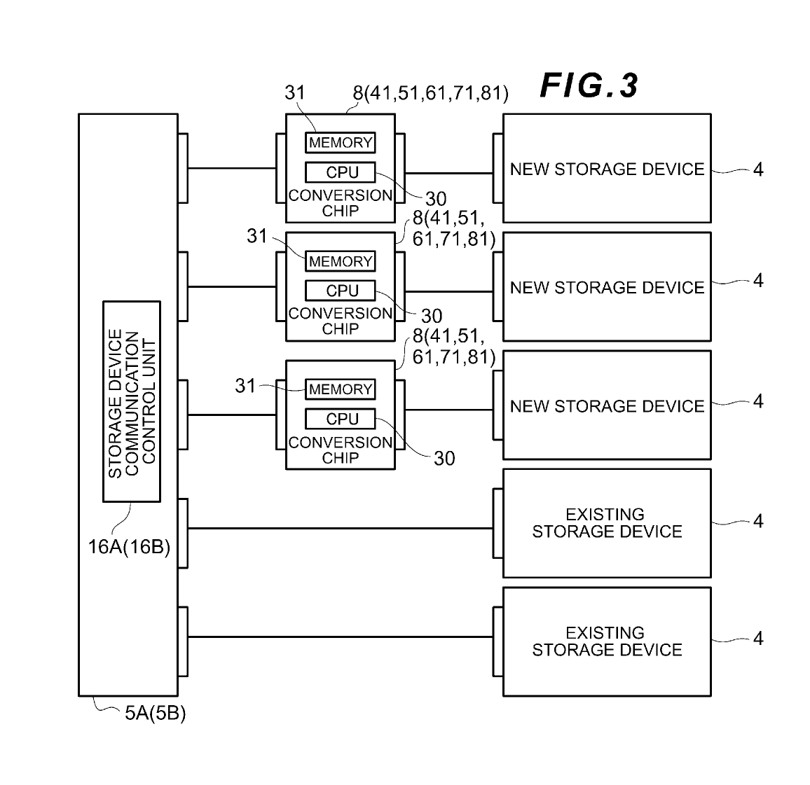

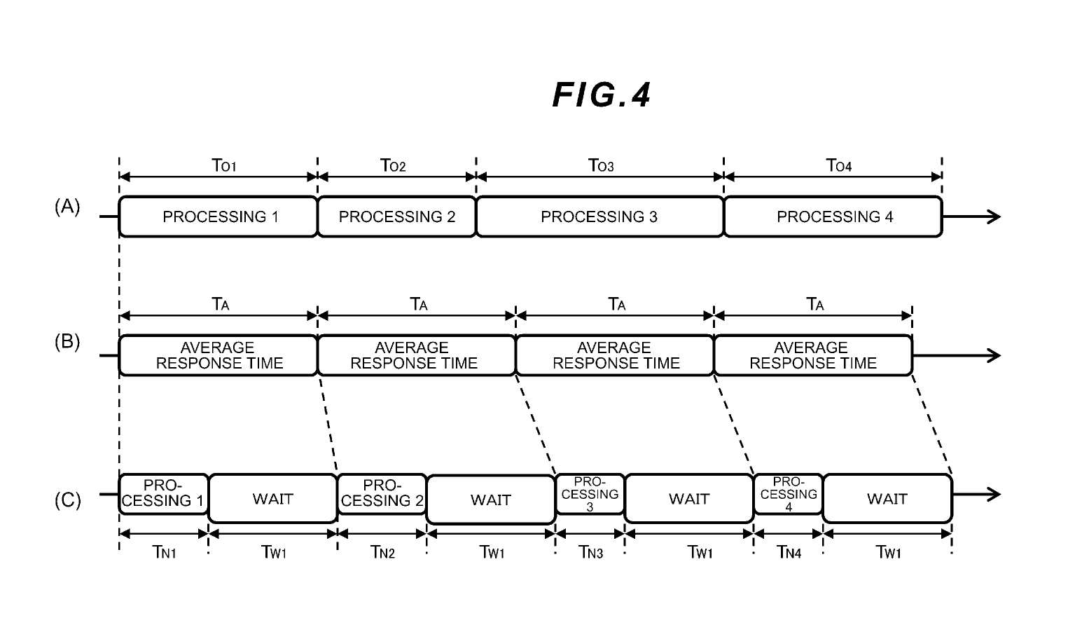

Practically, this conversion chip 8 includes information processing resources such as a CPU 30 and a memory 31 as shown in FIG. 3. For example, as shown in FIG. 4, the conversion chip 8 delays a response from the new storage devices 4 to the controller 5A, 5B to a command (read command or write command) from the controller 5A, 5B for a predetermined delay time (hereinafter referred to as the wait time) T_{W} (T_{W1}) as shown in FIG. 4 (C) in order to eliminate a time difference between the individual processing time T_{O1}, T_{O2}, and so on (FIG. 4 (A)) of the existing storage devices constituting the ECC group and the individual processing time T_{N1}, T_{N2}, and so on (FIG. 4 (C)) of the new storage devices.

Specifically speaking, if the conversion chip 8 transmits a command given from the storage device communication control unit 16A, 16B for the controller 5A, 5B to a corresponding new storage device 4 and then receives a report from the new storage device 4 that the relevant processing for the command has terminated (hereinafter referred to as a command termination report), the conversion chip 8 does not immediately transfers the command termination report to the storage device communication control unit 16A, 16B, but waits for the expiration of the wait time T_{W} after the reception of the relevant command termination report and then transfers the relevant command termination report to the storage device communication control unit 16A, 16B.

In the case of this embodiment, such wait time T_{W} is previously decided by, for example, a system administrator as average response time T_{A} (FIG. 4 (B)) which is an average value of the response time T_{O1}, T_{O2}, and so on (FIG. 4 (A)) of the existing storage devices 4 constituting the ECC group, and is set to the conversion chip 8 in advance. It should be noted that the response time of the existing storage devices 4 herein used means a period of time after the storage device communication control unit 16A, 16B for the controller 5A, 5B transmits a command to the existing storage device 4 until the relevant storage device communication control unit 16A, 16B receives a command termination report about that command.

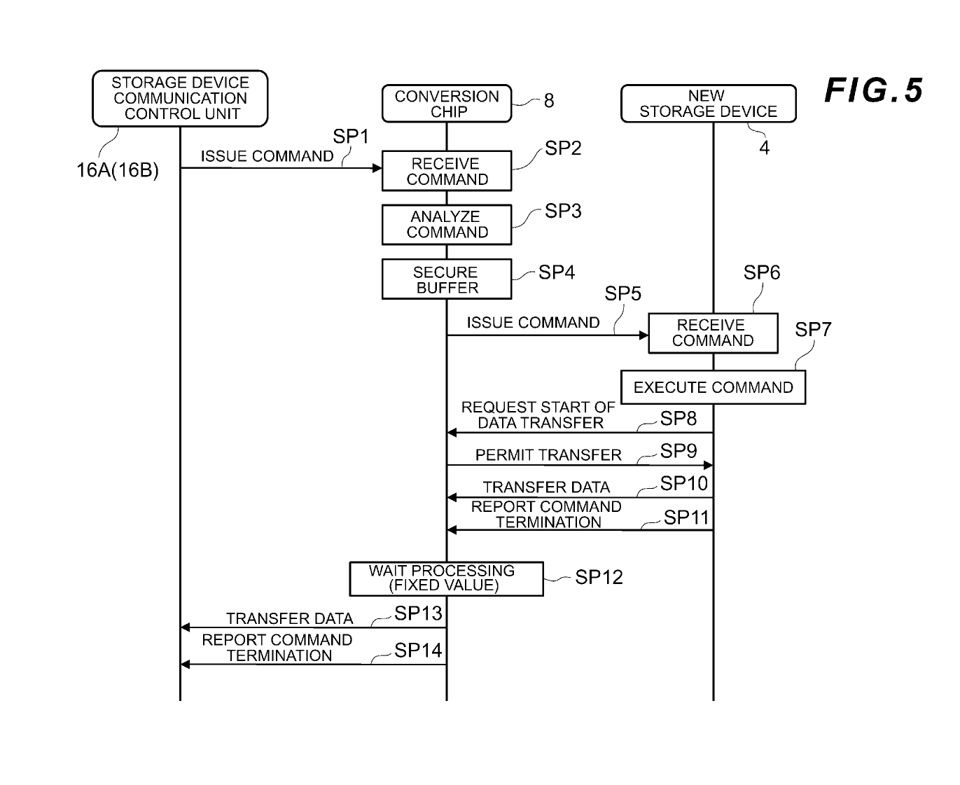

FIG. 5 shows the flow of a series of processing executed among the storage device communication control unit 16A, 16B for the controller 5A, 5B, the conversion chip 8, and the new storage device 4 in relation with the response time control function according to the embodiment described above.

This series of processing is started by the storage device communication control unit 16A, 16B for the controller 5A, 5B which has received a read command from the host computer 2A, 2B, by issuing a first command in accordance with the read command to the conversion chip 8 (SP1).

After receiving this first command (SP2), the conversion chip 8 analyzes, for example, the command type of the first command (SP3); and if the first command is a read command, the conversion chip 8 secures a storage area of the same capacity as that of read data in the memory 31 (FIG. 2) (SP4). Then, the conversion chip 8 issues a second command in accordance with the first command received in step SP2 to the storage device 4 (SP5).

After receiving this second command (SP6), the storage device 4 executes read processing in accordance with the second command (SP7). Meanwhile, the storage device 4 issues a data transfer start request for the data obtained by this read processing to the conversion chip 8 (SP8).

After receiving a transfer permission command from the conversion chip 8 in response to this data transfer start request (SP9), the storage device 4 transfers the data specified by the second command to the conversion chip 8 (SP10). As a result, the conversion chip 8 stores the data then transferred from the storage device 4 in the storage area secured in the memory 31 in step SP4. Furthermore, after transferring such data to the conversion chip 8, the storage device 4 transmits a command termination report to the conversion chip 8 (SP11) and then terminates the read processing for the second command received in step SP6.

Meanwhile, after receiving this command termination report, the conversion chip 8 executes wait processing for delaying the transfer of the read data received in step SP10 to the controller 5A, 5B for the predetermined wait time T_{W} (SP12). Then, after the elapse of the above-mentioned wait time T_{W} since the reception of the command termination report, the conversion chip 8 transfers the read target data transferred from the storage device 4 in step SP10 to the storage device communication control unit 16A, 16B for the controller 5A, 5B (SP13). Furthermore, after transferring such data to the controller 5A, 5B, the conversion chip 8 transmits a command termination report to the storage device communication control unit 16A, 16B (SP14) and then terminates the processing for the second command received in step SP2 (first response time control processing).

It should be noted that while the above-mentioned FIG. 5 shows an example of a case where a read command is transmitted from the storage device communication control unit 16A, 16B for the controller 5A, 5B to the conversion chip 8, a flow of processing is the same in a case where a write command is given from the host computer 2A, 2B to the controller 5A, 5B and a first command (write command) in accordance with this write command is transmitted from the storage device communication control unit 16A, 16B to the conversion chip 8.

(1-3) Advantageous Effects of This Embodiment

With the computer system 1 according to this embodiment as described above, a response from the relevant new storage device 4 to the command (first command) transmitted to the new storage device 4 from the storage device communication control unit 16A, 16B for the controller 5A, 5B is delayed for the specified wait time T_{W} at the conversion chip 8 and is then transferred to the storage device communication control unit 16A, 16B. As a result, the response performance of the new storage device 4 can be reduced apparently.

Accordingly, the response performance of the existing storage devices 4 and the new storage devices 4 as recognized by the controllers 5A, 5B can be substantially equalized, it is possible to effectively prevent the resources from being occupied due to accumulation of commands only in command queues corresponding to part of storage devices 4 constituting the same ECC group and realize a computer system capable of effectively preventing degradation of the response performance of the entire system.

Furthermore, since the response performance of the new storage devices 4 can be apparently reduced, it is not necessary to replace all the existing storage devices 4 constituting the ECC group with new storage devices 4, thereby making it possible to curb management cost increase.

(2) Embodiment 2

Referring to FIG. 1, the reference numeral 40 represents a computer system according to Embodiment 2. This computer system 40 is configured in the same manner as the computer system 1 according to Embodiment 1, except that wait time T_{W} used in response time control processing executed by a conversion chip 41 is different.

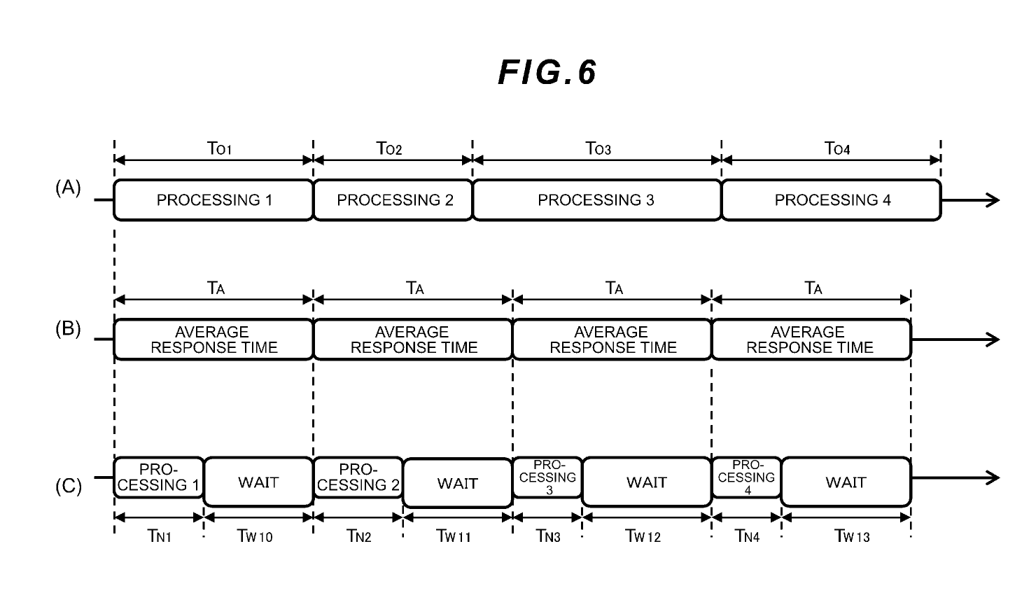

Practically, with the computer system 1 according to Embodiment 1, such wait time T_{W} is set as a fixed value; however, with the computer system 40 according to this embodiment as shown in FIG. 6, the difference between processing time T_{N1}, T_{N2}, and so on of the new storage device 4 (FIG. 6 (C)) and average response time T_{A} of the existing storage devices 4 (FIG. 6 (B)) is calculated for each processing and the difference is then used as wait time T_{W} (T_{W10}, T_{W11}, and so on) (FIG. 6 (C)) for the processing.

Accordingly, this computer system 40 is designed so that apparent processing time of each processing in the new storage devices 4 can be always made to correspond to the average response time T_{A} of the old storage devices 4.

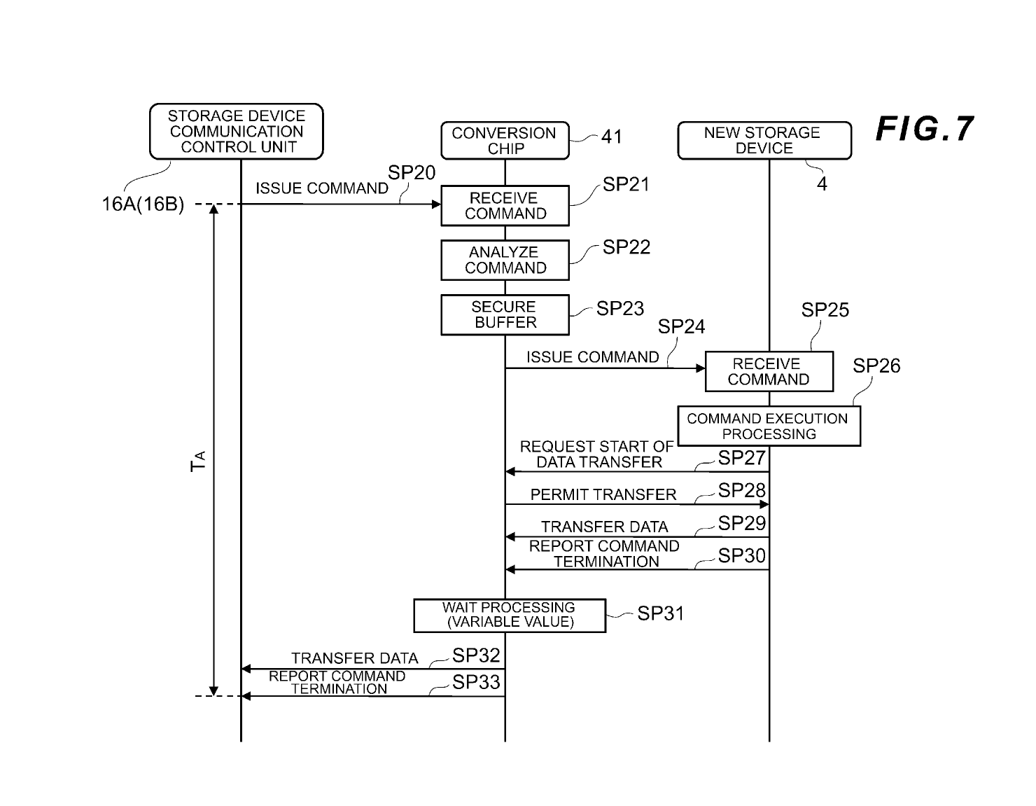

FIG. 7 shows a flow of a series of processing executed among the storage device communication control unit 16A, 16B for the controller 5A, 5B, the conversion chip 41, and the new storage device 4 in relation to the above-described response time control function according to this embodiment.

In this series of processing shown in FIG. 7, steps from SP20 to SP30 are processed in the same manner as steps from SP1 to SP11 according to Embodiment 1.

After receiving a command termination report (SP30) from the new storage device 4, the conversion chip 41 executes the wait processing according to this embodiment described above (SP31).

Specifically speaking, for example, the conversion chip 41 calculates the difference between a period of time from the issuance of a second command to the new storage device 4 in step SP24 to the reception of a command termination report (that is, processing time of the processing in the new storage device 4) and the average response time T_{A} of the existing storage devices 4, which is provided in advance.

Furthermore, the conversion chip 41 recognizes the period of time then calculated to be the wait time T_{W}, waits for the expiration of this wait time T_{W} after receiving the command termination report from the new storage device 4. Subsequently, if the wait time T_{W} has elapsed since receiving the command termination report from the new storage device 4, the conversion chip 41 transfers the read data received in step SP29 to the storage device communication control unit 16A, 16B for the controller 5A, 5B (SP32).

Then, the conversion chip 41 transmits a command termination report to the storage device communication control unit 16A, 16B (SP33) and then terminates the processing for the second command received in step SP21 (second response time control processing).

With the computer system 40 according to this embodiment as described above, the difference between the processing time T_{N1}, T_{N2}, and so on of the new storage devices 4, and the average response time T_{A} of the existing storage devices 4 is used as the wait time T_{W} (T_{W10}, T_{W11}, and so on) for the processing. So, as in Embodiment 1, the response performance of the existing storage devices 4 and the new storage devices 4 as recognized by the controllers 5A, 5B can be substantially equalized.

Accordingly, it is possible to effectively prevent the resources from being occupied due to accumulation of commands only in command queues corresponding to part of the storage devices 4 constituting the same ECC group and realize a computer system capable of effectively preventing degradation of the response performance of the entire system.

(3) Embodiment 3

Referring to FIG. 1, the reference numeral 50 represents a computer system according to Embodiment 3. This computer system 50 is configured in the same manner as the computer system 40 according to Embodiment 2, except that the processing content of wait processing in the conversion chip 51 is different.

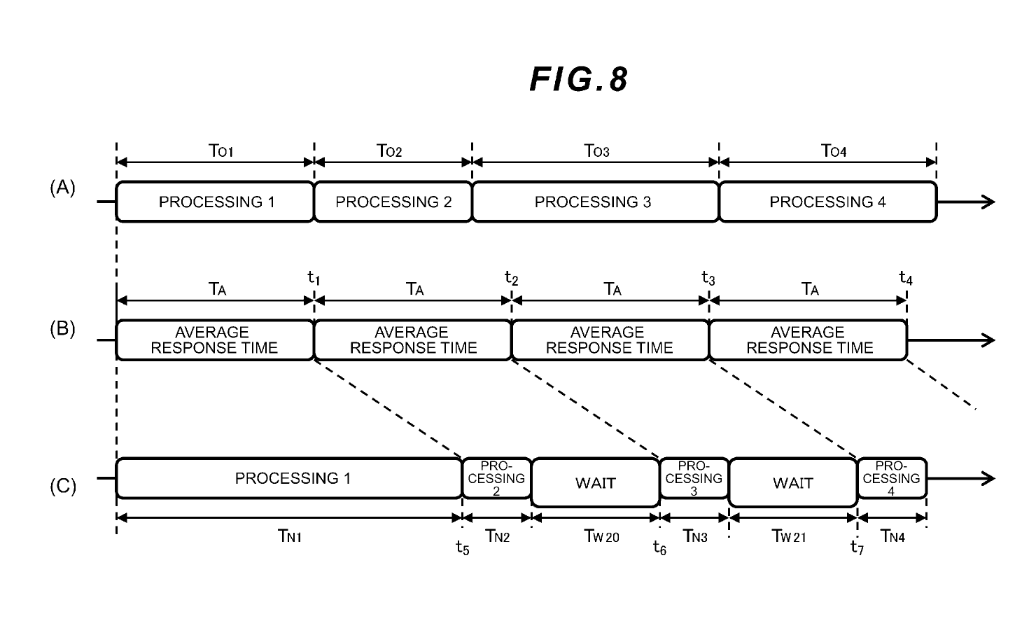

FIG. 8 shows a case where with the computer system 40 according to Embodiment 2, processing time T_{N1} of a part of processing (processing 1) temporarily becomes longer in the new storage device 4 due to the occurrence of a retry or for other reasons. As is apparent from this FIG. 8, if the processing time T_{N1} in the new storage device 4 becomes longer than the average response time T_{A} of the existing storage devices 4 with respect to in the computer system 40 according to Embodiment 2 and, for example, if the above-mentioned conversion chip 41 according to Embodiment 2 is used, the timing of termination of each processing of the new storage devices 4 (timing indicated by t₅, t₆, t₇ in FIG. 8 (C) and hereinafter referred to as the processing termination timing) remains deviated from the target timing of termination of the processing based on the average response time T_{A} of the existing storage devices 4 (timing indicated by t₁, t₂, t₃, t₄ in FIG. 8 (B) and hereinafter referred to as the target processing termination timing).

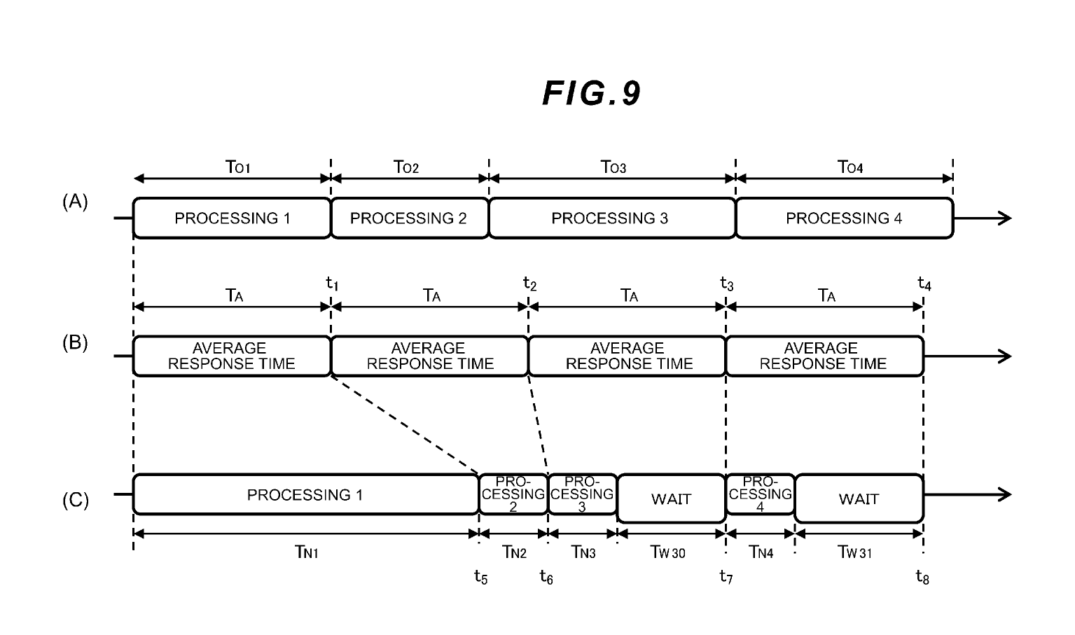

Therefore, if the processing termination timing of the new storage device 4 becomes slower than the target processing termination timing with respect to the computer system 50 according to this embodiment, a function stopping the wait processing (making the wait time 0) in the response time control processing until the processing termination timing of the new storage device 4 becomes close to the target processing termination timing for the processing as shown in FIGS. 9 (A) to (C) is installed in the conversion chip 51.

However, in the case of stopping the wait processing in the conversion chip 51 in this way, if the conversion chip 51 keeps stopping the wait processing even after the processing termination timing of the new storage device 4 becomes close to the target processing termination timing for the processing, the target processing termination timing for the processing often exceeds the processing termination timing of the new storage device 4 the last time the processing is stopped. In this case, a time difference between the apparent processing termination timing of the new storage device 4 (t₅ to t₈ in FIG. 9 (C)) and the target processing termination timing (t₁ to t₄ in FIG. 9 (C)) occurs, but this time difference will not be corrected later, which brings about the result against the intended purpose of provision of the conversion chip 51.

Therefore, with the computer system 50 according to this embodiment, a threshold is set to the number of times the wait processing should be stopped in the response time control processing executed by the conversion chip 51 (hereinafter referred to as the number of wait stop times). If the number of wait stop times exceeds such threshold, the wait processing in the response time control processing is resumed.

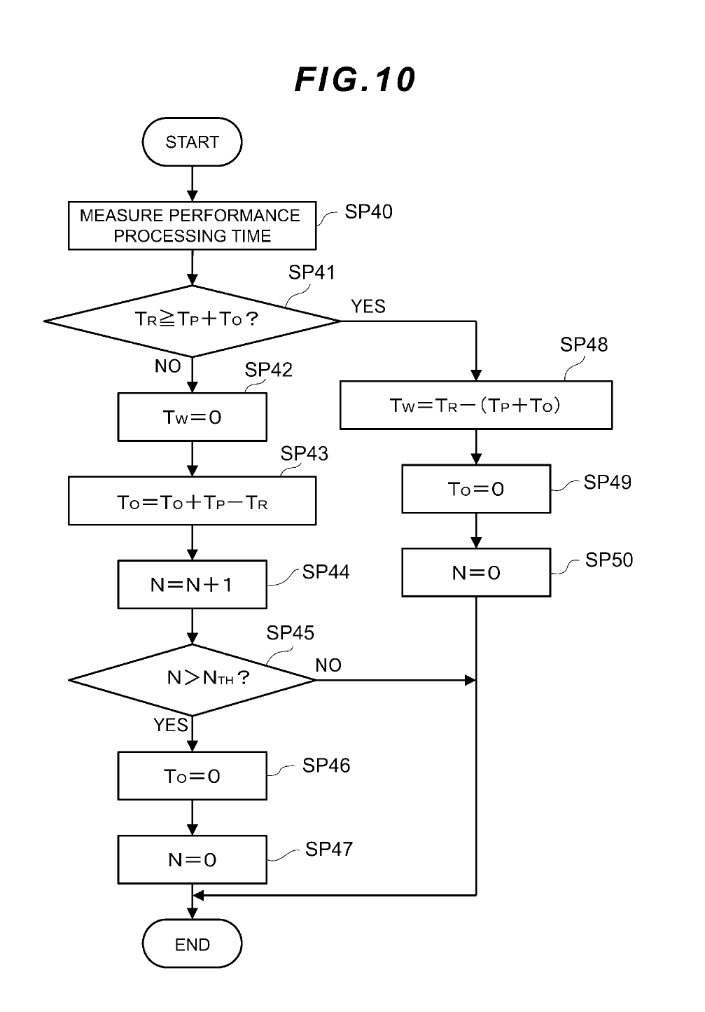

Concerning the above-mentioned response time control function in this embodiment, FIG. 10 shows a processing procedure of third response time control processing which is executed by the CPU 30 for the relevant conversion chip 51 in accordance with the relevant control program (not shown in the drawing) stored in the memory 31 for the conversion chip 51.

In this case, after receiving a second command from the storage device communication control unit 16A, 16B for the controller 5A, 5B, the CPU 30 starts this third response time control processing, that is, firstly transfers the second command to a new corresponding storage device 4, and then measures time it takes to receive a command termination report for the second command (hereinafter referred to as the processing execution time) (SP40).

Subsequently, the CPU 30 recognizes the processing execution time obtained as a result of the measurement as T_{P}, the average response time of the existing storage devices 4 as T_{R}, and the time difference between the target processing termination timing for the processing and the processing termination timing for the processing of the new storage device 4 (hereinafter referred to as a carried-over time) as T_{D}, and then judges whether the following math is satisfied or not.

[Math.1]

T_{R}≧T_{P}+T_{D} (1)

A negative judgment in this step means that the processing termination timing for the processing of the new storage device 4 is behind the target processing termination timing for the processing (i.e. the processing of the new storage device 4 is delayed). So, the CPU 30 then sets the wait time T_{W} for the processing to 0 (SP42).

Furthermore, the CPU 30 calculates the carried-over time T_{D} to be used in the next wait processing according to by the following math (SP43).

[Math.2]

T_{D}=T_{D}+T_{P}−T_{R} (2)

At the same time, the CPU 30 increments the number of times N (increases N by 1), which is counted by a counter (not shown in the drawing) (hereinafter referred to as the zero wait number-of-times counter), when the wait time T_{W} is continuously set to 0 (SP44) as shown in the following math.

[Math.3]

N=N+1 (3)

number-of-times counter

Subsequently, the CPU30 judges whether the number of times N when the wait time T_{W} is continuously set to 0 is larger than a predetermined threshold N_{TH} or not (SP45) as shown in this following math.

[Math.4]

N>N_{TH} (4)

Then, if a negative judgment is returned in this step, the CPU 30 terminates this response time control processing; and if an affirmative judgment is returned in this step, the CPU 30 resets the carried-over time T_{D} (SP46), furthermore resets a count value of the above-mentioned zero wait number-of-times counter (sets the counter value to 0) (SP47), and then terminates this third response time control processing.

Meanwhile, an affirmative judgment in step SP41 means that the processing termination timing for the processing of the new storage device 4 is not behind the target processing termination timing for the processing (i.e. the processing of the new storage device 4 is not delayed). So, the CPU 30 then calculates the wait time T_{W} to make the timing of transmitting a command termination report for the processing to the storage device communication control unit 16A, 16B correspond to the target processing termination timing for the processing according to the following math (SP48).

[Math.5]

T_{W}=T_{R}−(T_{P}+T_{D}) (5)

Subsequently, the CPU 30 resets the carried-over time T_{D} for the next wait processing (sets the carried-over time T_{D} to 0) (SP49) and also resets the number of times to continuously set the wait time to 0 (sets the number of times to continuously set the wait time to 0) (SP50), and then terminates this third response time control processing.

If the computer system 50 according to this embodiment as described above is used, even if the processing termination timing for the new storage device 4 is behind the target processing termination timing, it is possible to make the processing termination timing for the processing of the new storage device 4 become close to the target processing termination timing and eventually make the processing termination timing for the new storage device 4 correspond to the target processing termination timing. Therefore, as in the first embodiment, the response performance of the existing storage devices 4 and the new storage devices 4 as recognized by the controllers 5A, 5B can be substantially equalized,

Accordingly, it is possible to effectively prevent the resources from being occupied due to accumulation of commands only in command queues corresponding to part of the storage devices 4 constituting the same ECC group and realize a computer system capable of effectively preventing degradation of the response performance of the entire system.

(4) Embodiment 4

(4-1) Response Time Control Method According to This Embodiment

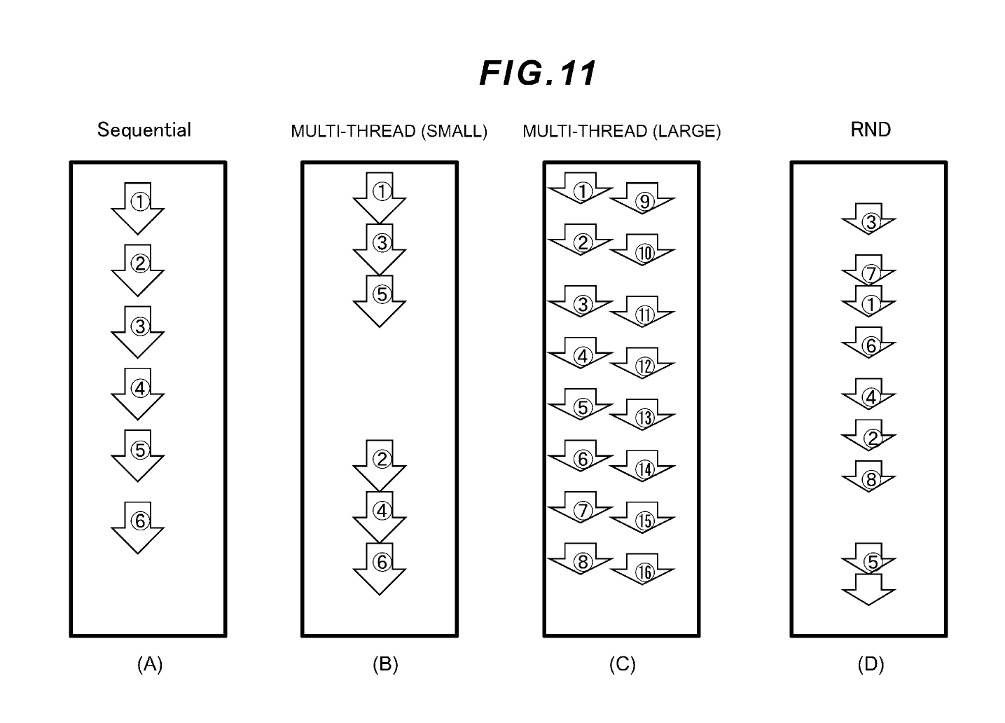

The average response time T_{A} of in a hard disk device normally varies depending on the type of a received command (a read command or a write command), the data length (length) of the target data specified by the command, and the block size of logical blocks; and, as shown in FIG. 11, the average response time T_{A} further varies depending on the sequentiality of read/write positions specified by individual commands.

For example, as a result of comparison between the response time in a case where sequential access is made to read data from, or write data to, sequential storage areas in the hard disk device as shown in FIG. 11(A), the response time in a case where sequential access is made to each of a plurality of areas in the hard disk device by a multi-thread method (this access method will be hereinafter referred to as the multi-thread access) as shown in FIG. 11(B) or FIG. 11(C), and the response time in a case where random access is made to randomly read data from, or write data to, arbitrary storage areas in the hard disk device as shown in FIG. 11 (D), the response time in the case of the sequential access is the fastest, and the response time in the case of the random access is the slowest.

Furthermore, in the case of the multi-thread access, the response time is faster as the number of threads is smaller, while the response time becomes slower as the number of threads increases. Therefore, in the examples shown in FIG. 11, the response time is slower in FIG. 11(C) than in FIG. 11(B).

This is because, if storage areas as the read destination/write destination specified by the individual commands are sequential, the read processing/write processing for a plurality of commands with respect to the sequential storage areas can be executed collectively, so that the response time is shortened by that amount of time.

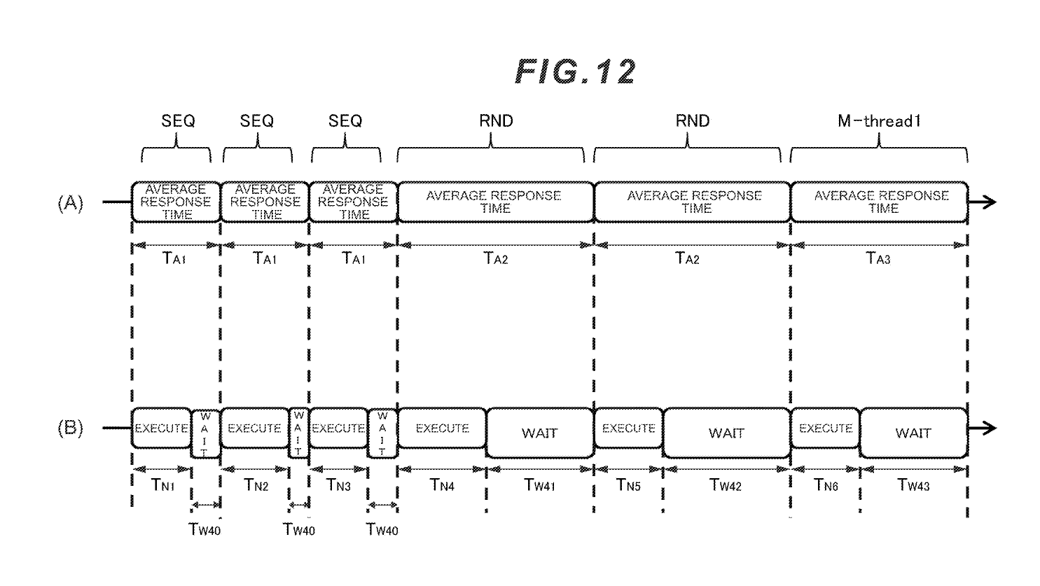

Therefore, with the computer system 60 (FIG. 1) according to this embodiment, as shown in FIGS. 12 (A) and (B), a conversion chip 61 (FIG. 1) judges an access pattern from the current host computer 2A, 2B (sequential access, multi-thread access, or random access) based on the plurality of latest commands, switches the average response time T_{A} (T_{A1}, T_{A2}, T_{A3}, and so on) to be used in the response time control processing in accordance with the above judgment result and the command content of the command received at that time (command type, data length of read data/write data, and logical block size), and then executes the response time control processing by the second embodiment (second response time control processing).

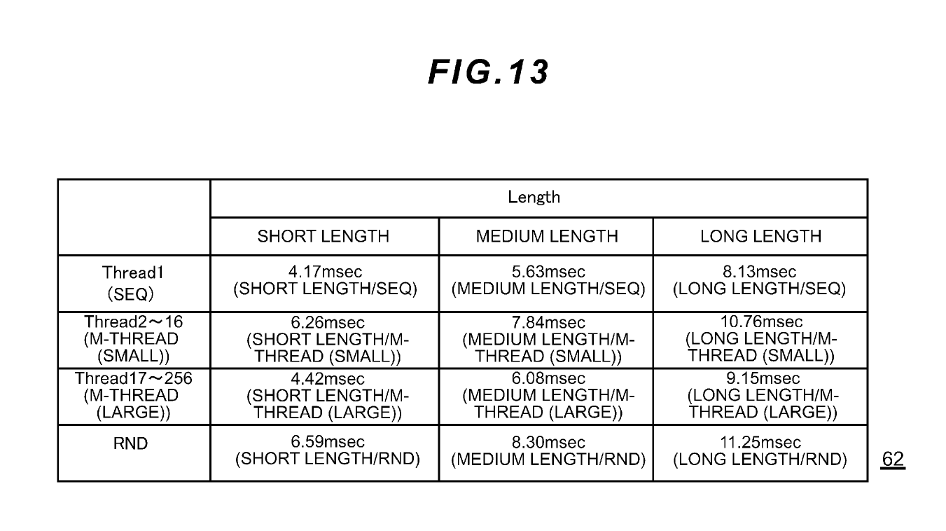

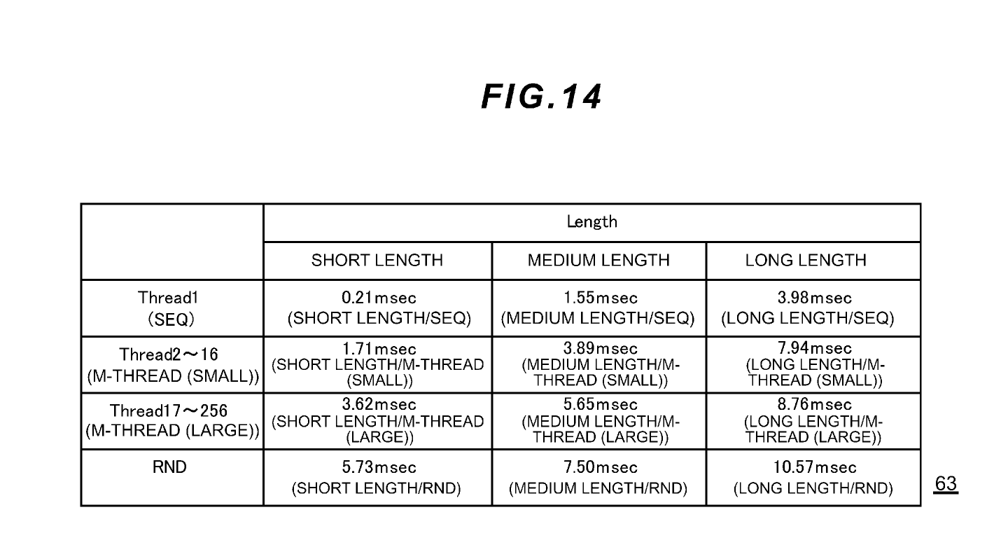

As a means for executing this type of response time control processing (hereinafter referred to as the fourth response time control processing), a read response time management table 62 shown in FIG. 13 and a write response time management table 63 shown in FIG. 14 are stored in the memory 31 for each conversion chip 61 (FIG. 3).

The read response time management table 62 is a table used to manage the average response time T_{A} determined in advance for each combination of the access pattern at the time of read access (sequential access, multi-thread access, and random access) and the data length of read data specified by a command. Furthermore, the write response time management table 63 is a table used to manage the average response time T_{A} determined in advance for each combination of an access pattern at the time of write access and the data length of write data specified by a command. Then, the read response time management table 62 and the write response time management table 63 are configured in a correspondence table form in which the access patterns are aligned vertically and the data lengths of the access target data specified by commands are aligned horizontally.

Incidentally, in FIGS. 13 and 14, the field stating Thread1 (SEQ) in a vertical column corresponds to sequential access, the field stating Thread 2 to Thread 16 (m-thread (small)) corresponds to multi-thread access of 2 to 16 threads, the field stating Thread 17 to Thread 256 (m-thread (large)) corresponds to multi-thread access of 17 to 256 threads, and the field stating RND corresponds to random access.

Furthermore, in FIG. 13 and FIG. 14, Short Length indicates a case where the data length of the access target data specified by the second command is equal to or less than a predetermined first threshold; Medium Length indicates a case where the data length of the access target data specified by the second command is more than the predetermined first threshold and equal to or less than a predetermined second threshold (first threshold<second threshold); and Long Length indicates a case where the data length of the access target data specified by the second command is more than the second threshold.

Therefore, the example in FIG. 13 shows that if the data length of the read data specified by the second command received at that time is Short length and the access pattern at that time is sequential access, 4.17 msec should be used as the average response time T_{A}; and if the data length of the read data specified by the second command is Medium length and the access pattern at that time is multi-thread access of 2 to 16 threads, 7.84 msec should be used as the average response time T_{A}.

Then, after receiving the second command from the storage device communication control unit 16A, 16B for the controller 5A, 5B, the conversion chip 61 selects either the read response time management table 62 or the write response time management table 63 as the relevant table in accordance with the type of the second command (read command or write command). Furthermore, the conversion chip 61 reads the average response time T_{A}, which should be applied at that time, from the read response time management table 62 or the write response time management table 63 in accordance with the data length of the access target data specified by the second command and the access pattern at that time, and executes the wait processing by Embodiment 2 mentioned above with reference to FIG. 5 by using the read average response time T_{A} (step SP12 in FIG. 5).

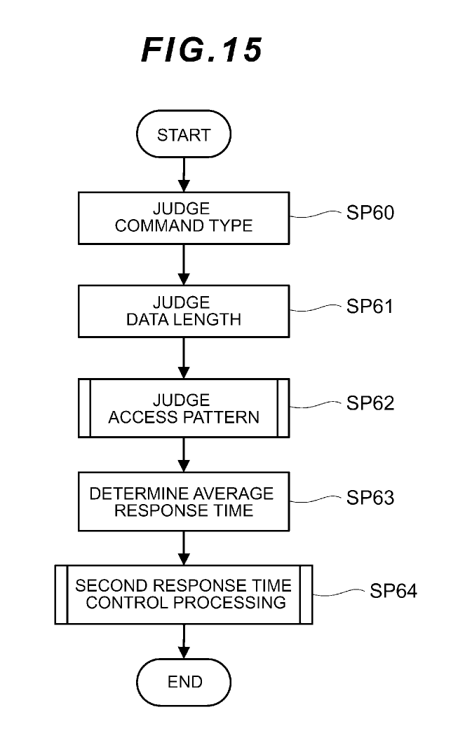

FIG. 15 shows of processing procedure of the fourth response time control processing executed by the CPU 30 for the relevant conversion chip 61 in accordance with the relevant control program stored in the memory 31 for the conversion chip 61 with respect to the above-described response time control function according to this embodiment.

In this case, after receiving a second command from the storage device communication control unit 16A, 16B for the controller 5A, 5B, the CPU 30 starts this fourth response time control processing, that is, firstly judges whether the second command is a read command or a write command (SP60).

Subsequently, the CPU 30 extracts the data length of the access target data specified by the second command from the second command then received , compares the extracted data length with the above-mentioned predetermined first and second thresholds, and judges whether the data length is short, medium, or long (SP61).

Subsequently, the CPU 30 judges the sequentiality of a data read/write position specified by the received second command and a read/write position specified by a second command received before the relevant second command; and then judges, in accordance with the result of the judgment, whether the access pattern at that time is either one of the sequential access, the multi-thread access of 2 to 16 threads (hereinafter referred to as the multi-thread access (small)), the multi-thread access of 17 to 256 threads (hereinafter referred to as the multi-thread access (large)), or the random access (SP62). It should be noted that the method for judging the sequentiality of the read/write positions specified by the second commands and the current access pattern will be described later.

Then, based on the result of the judgment in steps from SP60 to SP62, the CPU 30 extracts the average response time T_{A} according to the data length and the access pattern of the access target data specified by the second command at that time from the corresponding read response time management table 62 or write response time management table 63, and sets the extracted average response time T_{A} as the average response time T_{A} to be used in the wait processing for the second command (SP63).

Subsequently, the CPU 30 executes the second response time control processing according to Embodiment 2 described above with reference to FIG. 7 (SP64) and then terminates this fourth response time control processing.

(4-2) Access Pattern Determination Processing

Next, the specific processing content of the access pattern judgment processing executed in step SP62 of such fourth response time control processing will be explained. Firstly, the method executed by the conversion chip 61 for determining the sequentiality of the read/write positions specified by received second commands (hereinafter referred to as the received commands as necessary) will be explained.

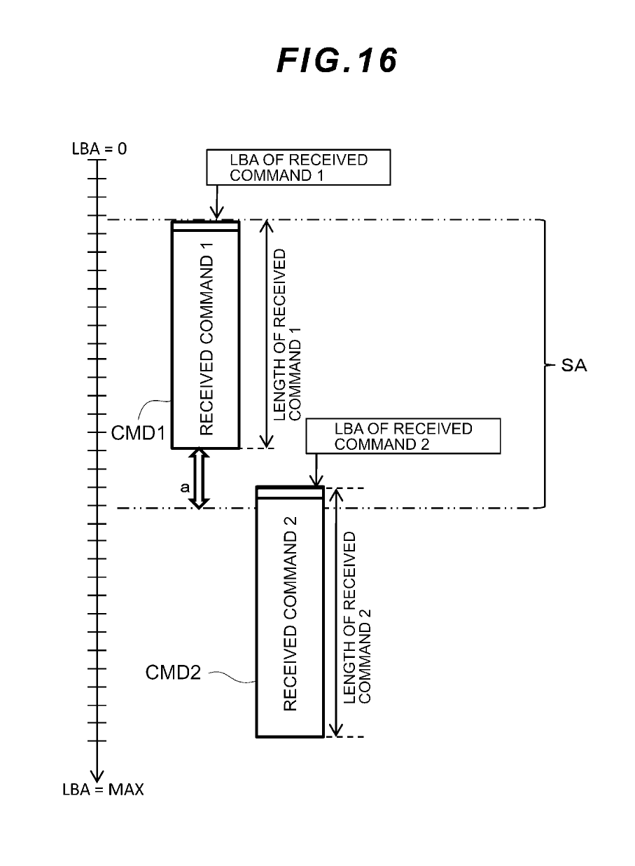

In this embodiment, as shown in FIG. 16, if a top block LBA of a read/write position specified by a certain received command (hereinafter referred to as the received command 2) CMD2 exists between a top block LBA of a read/write position specified by a received command before the received command 2 (hereinafter referred to as the received command 1) and the last block LBA of the entire storage area SA which is configured by adding the data length for a specified value a (hereinafter referred to as the adjustment value a) to the data length of the target data specified by the relevant received command 1 and, at the same time, if the received command 1 and the received command 2 are of the same command type (read command or write command), the CPU 30 for the conversion chip 61 determines that the read/write position specified by the received command 1 and the read/write position specified by the received command 2 are sequential.

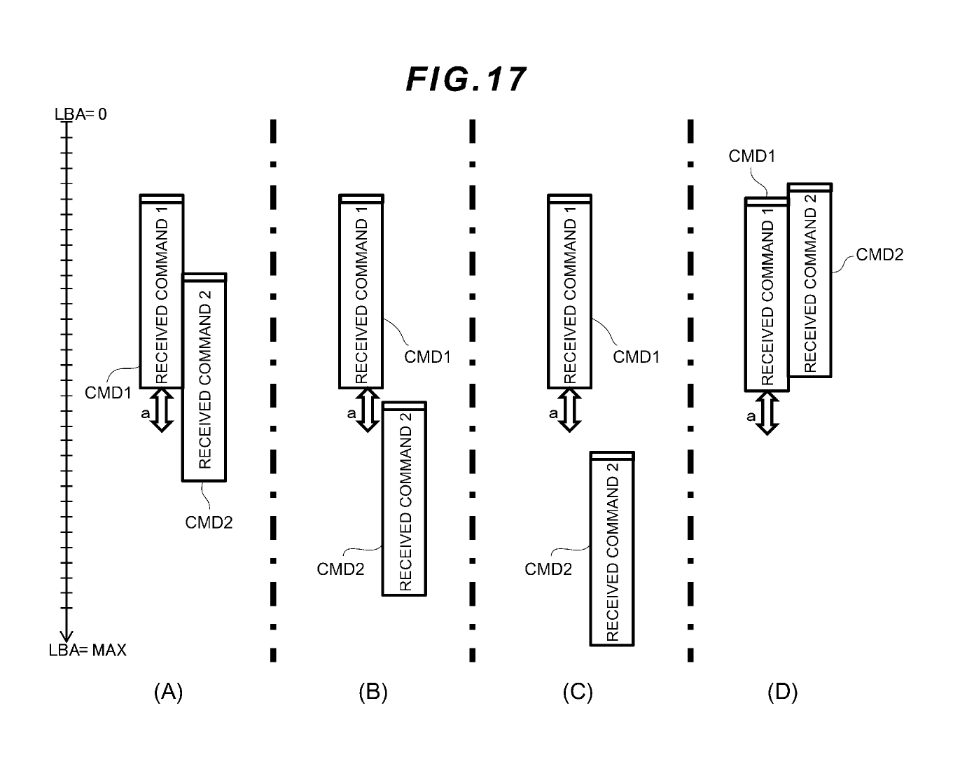

Therefore, for example, if the top block LBA of the read/write position specified by the received command 2 exists between the top block LBA of the read/write position specified by the received command 1 and the last block LBA as shown in FIG. 17 (A), and also if the top block LBA of the read/write position specified by the received command 2 exists in the range of the adjustment value a as shown in FIG. 17 (B), when the received command 1 and the received command 2 are of the same command type, the CPU 30 determines that the read/write position specified by the received command 1 and the read/write position specified by the received command 2 are sequential.

On the other hand, if the top block LBA of the read/write position specified by the received command 2 is larger than the last block LBA of the entire storage area which is configured by adding the data length for the adjustment value a to the read/write position specified by the received command 1 as in FIG. 17 (C) or smaller than the top block LBA of the read/write position specified by the received command 1 as in FIG. 17 (D), even if the received command 1 and the received command 2 are of the same command type, the CPU 30 determines that the read/write position specified by the received command 1 and the read/write position specified by the received command 2 are not sequential.

Then, the CPU 30 uses a certain number of (e.g. 512) the most-recently received commands as samples, counts the number of sets of received commands whose read/write positions specified by the received commands are sequential, from among the plurality of received commands, by using the above-described method for judging the sequentiality of the read/write positions specified by the received commands; and if the number of sets is one, the CPU 30 determines that the current access pattern is the sequential access; and if the number of sets is 0, the CPU 30 determines that the current access pattern is the random access. Furthermore, if the number of sets is 2 to 16, the CPU 30 determines that the current access pattern is the multi-thread access (small); and if the number of sets is 17 to 256, the CPU 30 determines that the current access pattern is the multi-thread access (large).

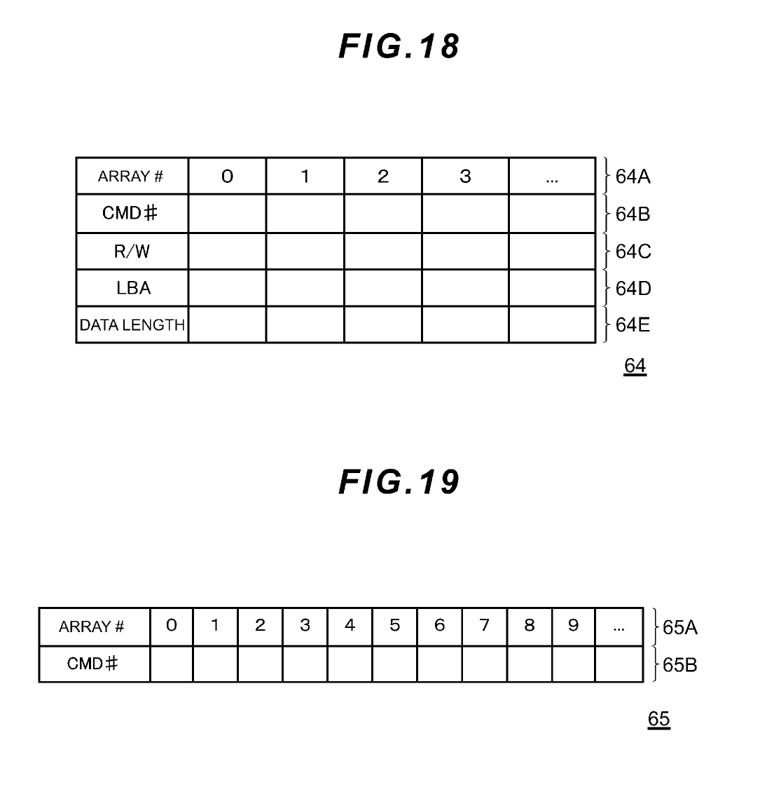

As a means for performing the above-mentioned access pattern judgment according to this embodiment, a thread management basic table 64 shown in FIG. 18 and a latest received command management table 65 shown in FIG. 19 are stored in the memory 31 for the conversion chip 61.

The thread management basic table 64 is a table used by the CPU 30 for the conversion chip 61 to manage specified information about each of the specified number of the most-recently received commands given from the controller 5A, 5B; and includes an array number field 64A, a command number field 64B, a command type field 64C, an LBA field 64D, and a data length field 64E as shown in FIG. 18.

The array number field 64A stores in advance, for example, a serial number starting with 0 as an array number. Furthermore, the command number field 64B stores a command number which the conversion chip 61 provides to the relevant received command. A serial number starting with 1 is used as this command number.

Furthermore, the command type field 64C stores a code indicating the type of the received command (read command or write command) and the LBA field 64D stores a block address of the top block of the read/write position specified by the received command. Furthermore, the data length field 64E stores the data length of the target data specified by the received command.

Furthermore, the latest received command management table 65 is a table used to judge the access pattern in accordance with the sequentiality of the read/write position specified by the received command; and includes an array number field 65A and a command number field 65B as shown in FIG. 19.

The array number field 65A stores in advance, for example, a serial number starting with 0 as an array number; and if another received command (hereinafter referred to as the other received command) whose read/write position is a storage area sequential to the read/write position specified by the corresponding received command (hereinafter referred to as the corresponding received command) exists, the command number field 65B stores the command number assigned to the relevant other received command; and if such other received command does not exist, the command number field 65B stores the command number assigned to such corresponding received command.

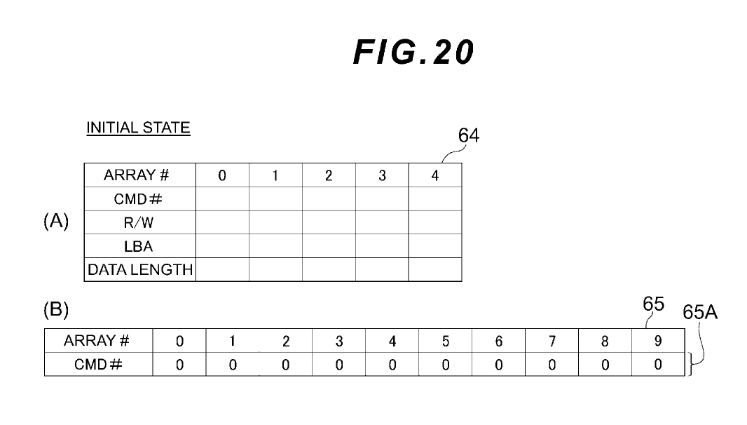

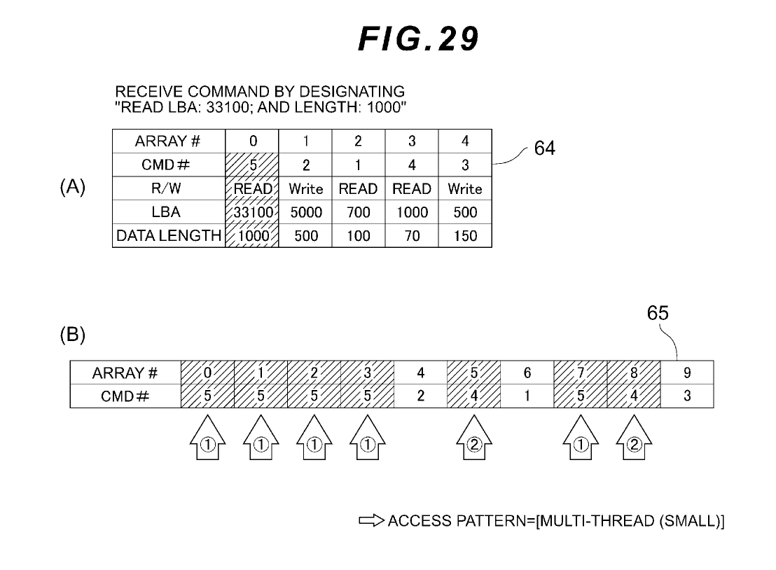

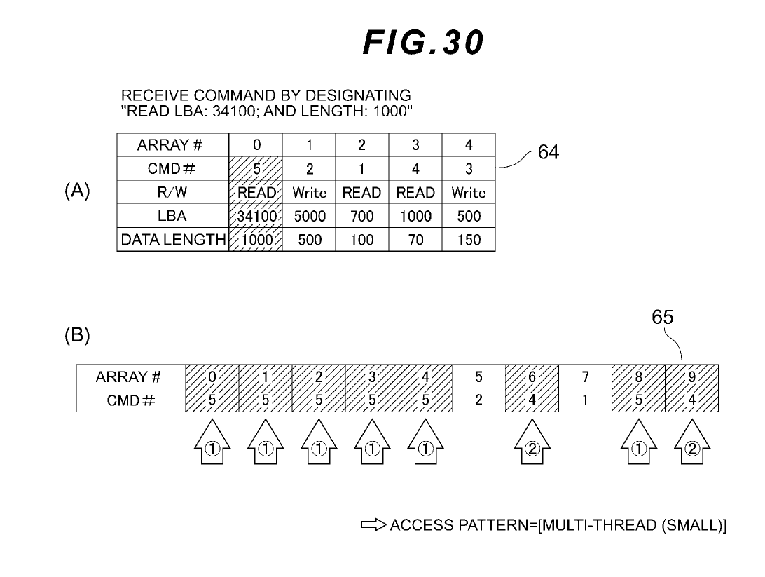

Now, specific examples of the access pattern judgment method according to this embodiment by using the above-mentioned thread management basic table 64 and the latest received command management table 65 will be explained with reference to FIGS. 20 to 31.

Firstly, in the initial state, as shown in FIGS. 20 (A) and (B), no information related to received commands is stored in any columns of the thread management basic table 64, and 0 is stored in the command number field 65B of each column of the latest received command management table 65.

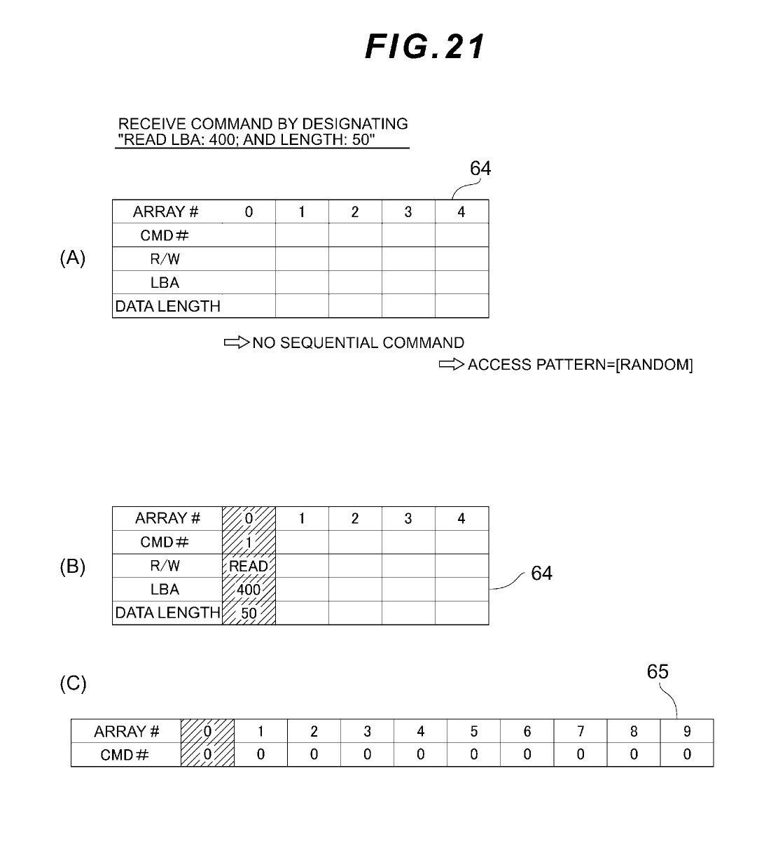

If a first command in response to a read command, which specifies 400 as the top block LBA of the read position and 50 as the data length of the read target data, is provided to the conversion chip 61 in the above-described state as shown in FIG. 21, the CPU 30 for the conversion chip 61 refers to the thread management basic table 64 and judges whether a received command specifying a storage area as a read/write position which is sequential to the read position specified by the currently received command (first command) exists in commands received in the past and registered in the relevant thread management basic table 64 (first commands) or not. If a negative judgment is returned in this step, the CPU 30 determines that the current access pattern is random (FIG. 21 (A)).

Then, the CPU 30 stores each piece of necessary information related to the currently received command in the row whose array number is 0 in the thread management basic table 64 as shown in FIG. 21 (B); and stores the command number assigned to the second command in the row whose array number is 0 in the latest received command management table 65 as shown in FIG. 21 (C).

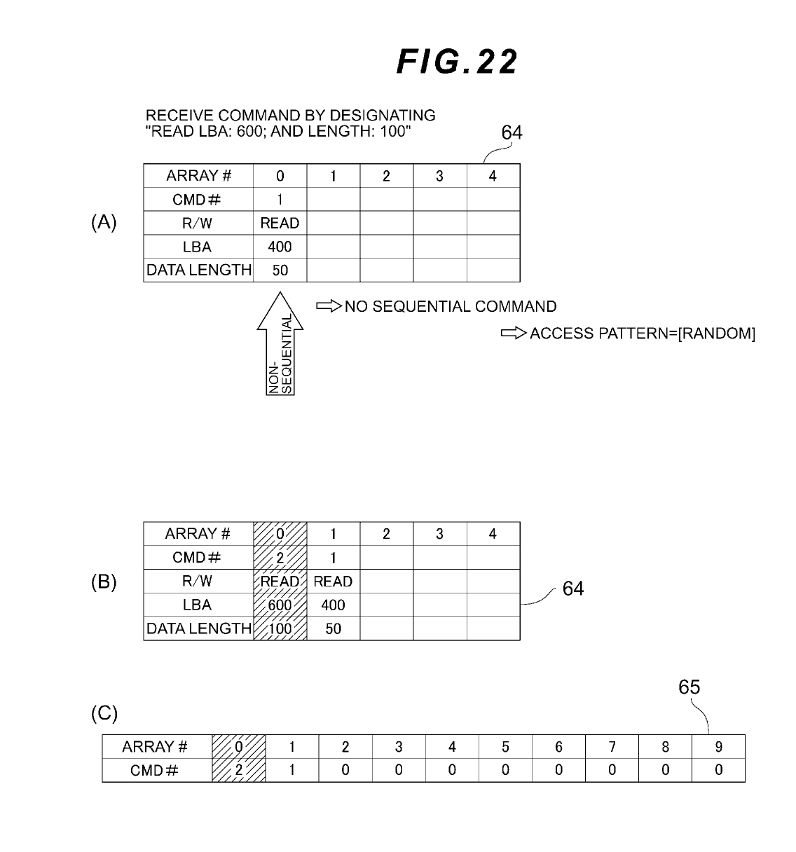

Next, if a first command in response to a read command, which specifies 600 as the top block LBA of the read position and 100 as the data length of the read target data, is provided to the conversion chip 61 as shown in FIG. 22, the CPU 30 for the conversion chip 61 refers to the thread management basic table 64 and judges whether a received command specifying a storage area as a read position which is sequential to the read position specified by the currently received command (first command) exists in the commands received in the past and registered in the relevant thread management basic table 64 (first commands) or not. In this case, also, if a negative judgment is returned as shown in FIG. 22 (A), the CPU 30 determines that the current access pattern is random (FIG. 22 (A)).

Then, as shown in FIG. 22 (B), after shifting the information stored in the command number field 64B, the command type field 64C, the LBA field 64D, and the data length field 64E respectively of the row in which the information corresponding to the received command is stored (which is, in this stage, only the row corresponding to the received command whose command number is 1 and such row will be hereinafter referred to as an entry), from among rows in the thread management basic table 64, to the row whose array number is larger by 1 respectively (this processing will be hereinafter referred to as shifting an entry of the thread management basic table 64), the CPU 30 stores each piece of the necessary information related to the currently received command in the row whose array number is 0 in the thread management basic table 64.

Furthermore, as shown in FIG. 22 (C), after shifting the command number stored in the command number field 65B of the row in which the information corresponding to the received command is stored (which is, at this stage, only the row corresponding to the received command whose command number is 1 and such row will be hereinafter also referred to as an entry), from among the rows in the latest received command management table 65, to the row whose array number is larger by 1 respectively (hereinafter this processing will be referred to as shifting an entry of the latest received command management table 65), the CPU 30 stores the command number assigned to this received command in the command number field 65B of the row whose array number is 0 in the latest received command management table 65.

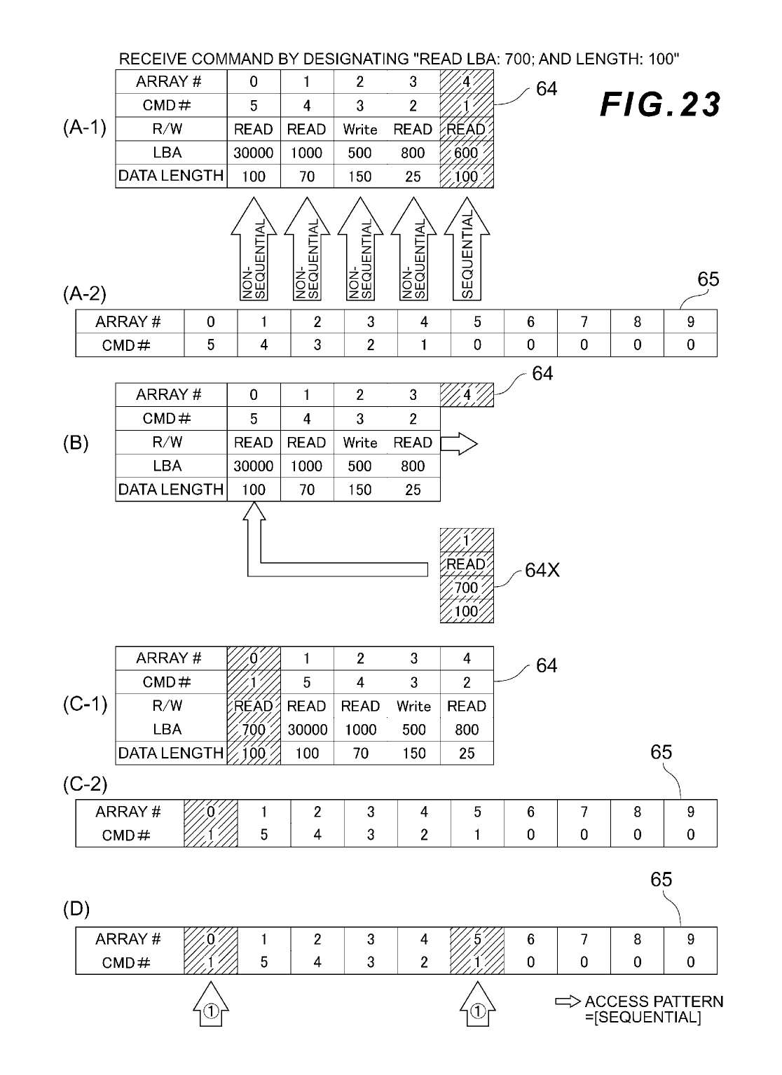

After that, if a second command in response to a read command, which specifies 700 as the top block LBA of the read position and 100 as the data length of the read target data, is provided to the conversion chip 61 as shown in FIG. 23 in the state in which the conversion chip 61 receives some second commands and the thread management basic table 64 is updated, for example, as in FIG. 23 (A-1), and the latest received command management table 65 is updated, for example, as in FIG. 23 (A-2), the CPU 30 for the conversion chip 61 refers to the thread management basic table 64 and judges whether a received command specifying a storage area as a read/write position which is sequential to the read position specified by the currently received command exists in the past received commands registered in the relevant thread management basic table 64 or not.

In this case, regarding the received command whose information is stored in the row whose array number in the thread management basic table 64 is 4 in FIG. 23 (A-1), its command type is read command and the top block LBA of the read position is 600, and the data length is 100. So, it is determined that the storage area is sequential to the read position specified by the currently received command. Accordingly, as shown in FIG. 23 (B), the CPU 30 then creates entry information 64X in which each piece of information stored in the LBA field 64D and the data length field 64E in the row whose array number is 4 in the thread management basic table 64 is rewritten to the information of the currently received command, shifts each entry whose array number of the thread management basic table 64 is 0 to 3, and then copies such entry information 64X to the row whose array number is 0 in the thread management basic table 64, as shown in FIG. 23 (C-1).

Furthermore, as shown in FIG. 23 (C-2), after shifting each entry of the latest received command management table 65, the CPU 30 stores the command number (1 in the example of FIG. 23 (C-1)) assigned to the currently received command to the command number field 65B in the row whose array number is 0 in the latest received command management table 65.

Subsequently, the CPU 30 detects how many sets of entries whose command numbers are the same exist in the latest received command management table 65; and judges the current access pattern based on this detection result. For example, in the example of FIG. 23 (C-2), there is only one such set of entries, that is, the entry whose array number is 0 and the entry whose array number is 5 as shown in FIG. 23 (D). As a result, the number of current threads can be presumed to be one. So, the CPU 30 determines that the current access pattern is sequential access.

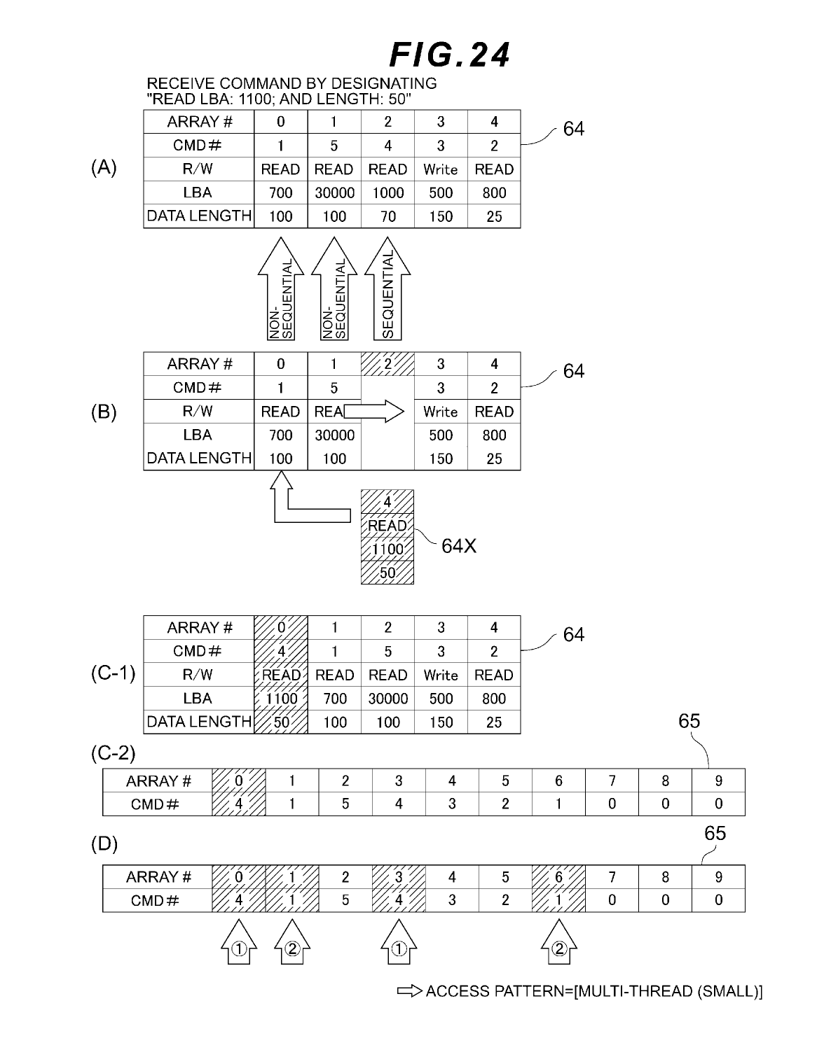

Subsequently, if a first command in response to a read command, which specifies 1100 as the top block LBA of the read position and 50 as the data length of the read target data, is provided to the conversion chip 61 as shown in FIG. 24, the CPU 30 for the conversion chip 61 refers to the thread management basic table 64 and judges whether a received command specifying a storage area as a read/write position which is sequential to the read position specified by the currently received command exists in the past received commands registered in the relevant thread management basic table 64 or not.

In this case, regarding the received command whose information is stored in the row whose array number in the thread management basic table 64 is 2 in FIG. 24 (A), the command type of the received command is read command and the top block LBA of the read position is 1000 while the data length is 70. So, it is determined that the storage area is sequential to the read position specified by the currently received command. Accordingly, as shown in FIG. 24 (B), the CPU 30 then creates entry information 64X in which each piece of information stored in the LBA field 64D and the data length field 64E in the row whose array number is 2 in the thread management basic table 64 is rewritten to the information of the currently received command, shifts each entry whose array number of the thread management basic table 64 is 0 and 1, and then copies such entry information 64X to the row whose array number is 0 in the thread management basic table 64, as shown in FIG. 24 (C-1).

Furthermore, as shown in FIG. 24 (C-2), after shifting each entry of the latest received command management table 65, the CPU 30 stores the command number (4 in the example of FIG. 24 (C-1)) provided to the currently received command to the command number field 65B in the row whose array number is 0 in the latest received command management table 65.

Subsequently, the CPU 30 detects how many sets of entries whose command numbers are the same exist in the latest received command management table 65; and judges the current access pattern based on this detection result. For example, in the example of FIG. 24 (C-2), there are two sets of such entries, that is, a set of entries whose array numbers are 0 and 3 respectively and a set of entries whose array numbers are 1 and 6 as shown in FIG. 24 (D). As a result, the number of current threads can be presumed to be two. So, the CPU 30 determines that the current access pattern is multi-thread access (small).

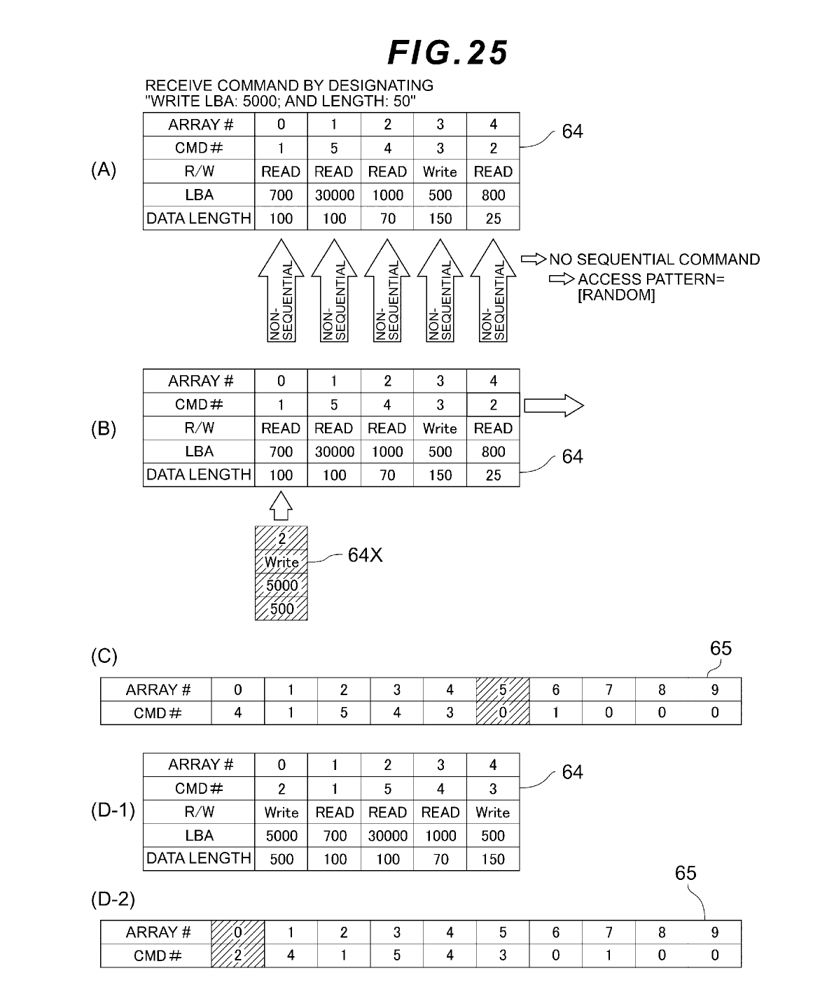

Subsequently, as shown in FIG. 25, if a first command in response to a write command, which specifies 5000 as the top block LBA of the write position and 500 as the data length of the write target data, is provided to the conversion chip 61, the CPU 30 for the conversion chip 61 refers to the thread management basic table 64 and judges whether a received command specifying a storage area as a read/write position which is sequential to the write position specified by the currently received command exists in the past received commands registered in the relevant thread management basic table 64 or not. In this case, a negative result is acquired from this example as shown in FIG. 25 (A) and, therefore, the CPU 30 determines that the current access pattern is random.

Accordingly, as shown in FIGS. 25 (B) and (D-1), the CPU 30 then shifts each entry in the thread management basic table 64, and creates entry information 64X corresponding to the currently received command by using the command number of the entry which is pushed out of the thread management basic table 64 at that time and adds this entry information 64X to the row whose array number is 0 in the thread management basic table 64.

Furthermore, along with the above-described processing, the CPU 30 updates (clears) the command number stored in the command number field 65B of the row in the latest received command management table 65 corresponding to the entry pushed out of the thread management basic table 64 as described above to 0 as shown in FIG. 25 (C). Furthermore, the CPU 30 shifts each entry of the latest received command management table 65 and stores the command number assigned to the currently received command to the command number field 65B in the row whose array number is 0 in the relevant latest received command management table 65, as shown in FIG. 25 (D-2).

Incidentally, in this case, the current access pattern is already determined to be random as described above with reference to FIG. 25 (A). So, the access pattern judgment based on the latest received command management table 65 will not be performed.

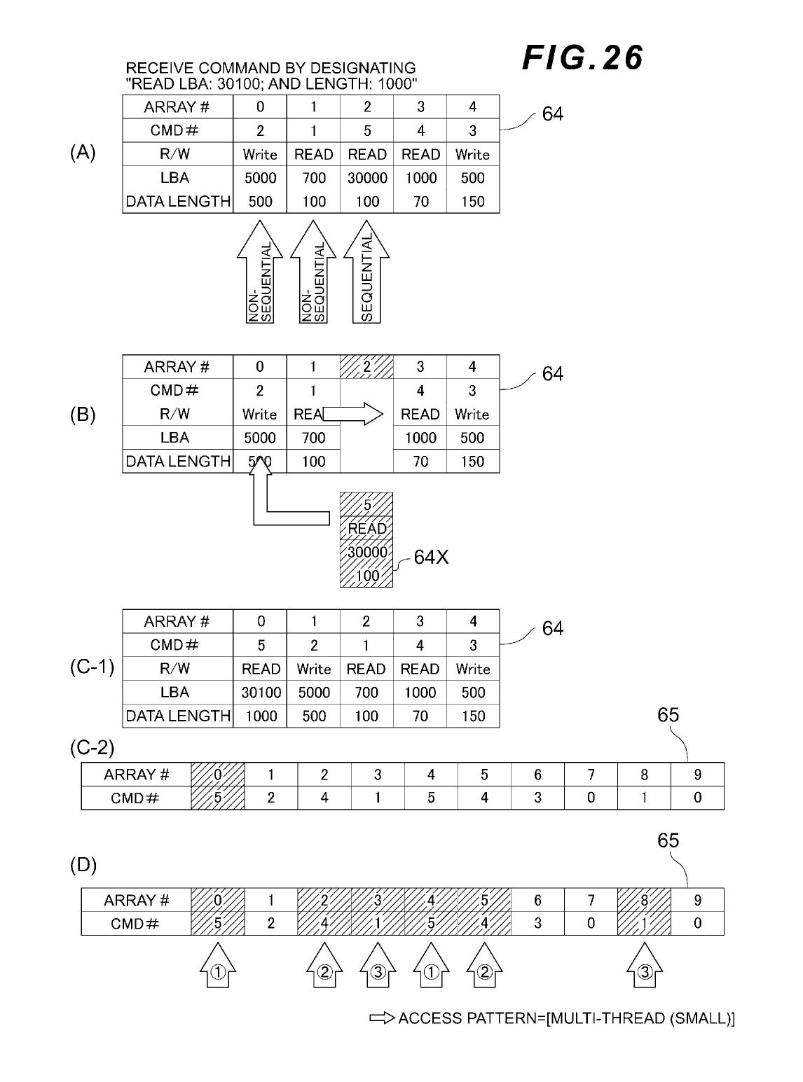

Subsequently, if a first command in response to a read command, which specifies 30100 as the top block LBA of the read position and 1000 as the data length of the read target data, is provided to the conversion chip 61 as shown in FIG. 26, the CPU 30 for the conversion chip 61 refers to the thread management basic table 64 and judges whether a received command specifying a storage area as a read/write position which is sequential to the read position specified by the currently received command exists in the past received commands registered in the relevant thread management basic table 64 or not.

In this case, regarding the received command whose information is stored in the row whose array number in the thread management basic table 64 is 2 in FIG. 26 (A), the command type of the received command is read command and the top block LBA of the read position is 30000, and the data length is 100. So, it is determined that the storage area is sequential to the read/write position specified by the currently received command. Accordingly, as shown in FIG. 24 (B), the CPU 30 then creates entry information 64X in which each piece of information stored in the LBA field 64D and the data length field 64E in the row whose array number is 2 in the thread management basic table 64 is rewritten to the information of the currently received command, shifts each entry whose array number of the thread management basic table 64 is 0 and 1, and then copies such entry information 64X to the row whose array number is 0 in the thread management basic table 64, as shown in FIG. 26 (C-1).

Furthermore, as shown in FIG. 26 (C-2), after shifting each entry of the latest received command management table 65, the CPU 30 stores the command number (5 in the example of FIG. 26 (C-1)) assigned to the currently received command to the command number field 65B in the row whose array number is 0 in the latest received command management table 65.

Subsequently, the CPU 30 detects how many sets of entries whose command numbers are the same exist in the latest received command management table 65; and judges the current access pattern based on this detection result. For example, in the case of FIG. 26 (C-2), there are three sets of such entries, that is, a set of entries whose array numbers are 0 and 3 respectively, a set of entries whose array numbers are 1 and 6 respectively, and a set of entries whose array numbers are 3 and 8 as shown in FIG. 26 (D). As a result, the number of current threads can be presumed to be three. So, the CPU 30 determines that the current access pattern is multi-thread access (small).

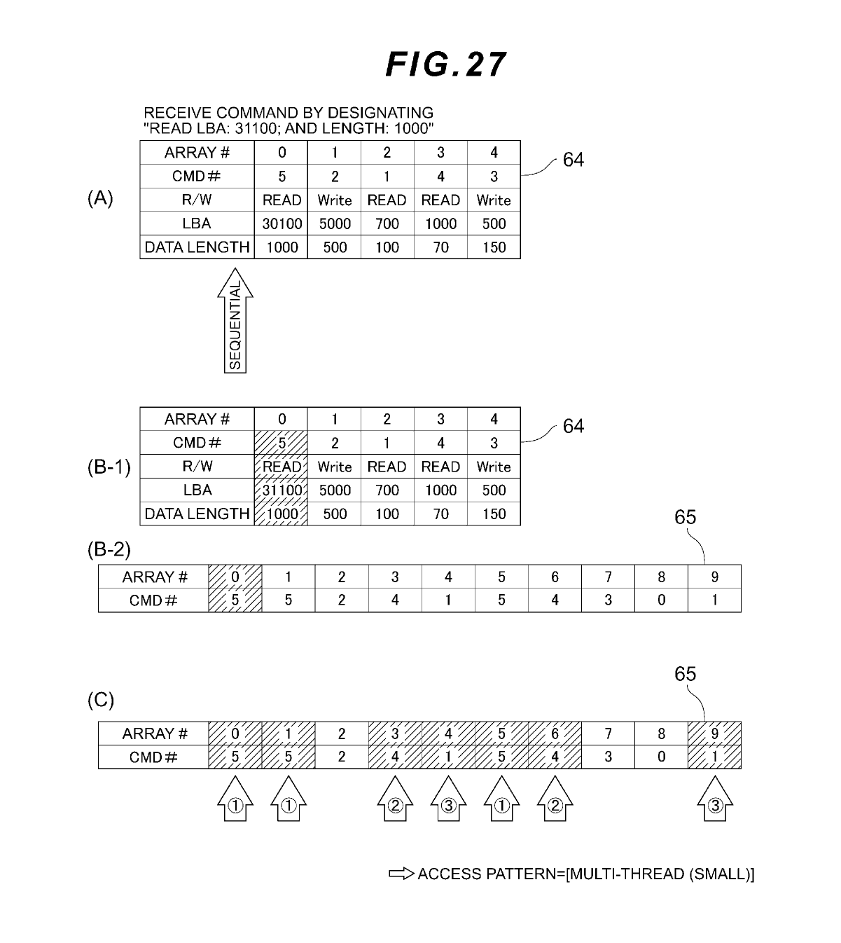

Next, if a first command in response to a read command, which specifies 31100 as the top block LBA of the read position and 1000 as the data length of the read target data, is provided to the conversion chip 61 as shown in FIG. 27, the CPU 30 for the conversion chip 61 refers to the thread management basic table 64 and judges whether a received command specifying a storage area as a read/write position which is sequential to the read position specified by the currently received command exists in the past received commands registered in the relevant thread management basic table 64 or not.

In this case, regarding the received command whose information is stored in the row whose array number in the thread management basic table 64 is 0 in FIG. 27 (A), the command type of the received command is read command and the top block LBA of the read position is 30100, and the data length is 1000. So, it is determined that the storage area is sequential to the read position specified by the currently received command. Accordingly, as shown in FIG. 27 (B-1), the CPU 30 then creates entry information, in which each piece of information stored in the command type field 64C, the LBA field 64D and the data length field 64E in the row whose array number is 0 in the thread management basic table 64 is rewritten to the information of the currently received command; and copies the created entry information to the command number field 64B, the command type field 64C, the LBA field 64D and the data length field 64E in the row whose array number is 0 in the thread management basic table 64. As a result, in this case, it is only necessary to update the entry in the row whose array number is 0 in the thread management basic table 64 with the information of the currently received command.

Furthermore, as shown in FIG. 27 (B-2), after shifting each entry of the latest received command management table 65, the CPU 30 stores the command number (5 in the example of FIG. 27 (B-1)) assigned to the currently received command to the command number field 65B in the row whose array number is 0 in the latest received command management table 65.

Subsequently, the CPU 30 detects how many sets of entries whose command numbers are the same exist in the latest received command management table 65; and judges the current access pattern based on this detection result. For example, in the example of FIG. 27 (B-2), there are three sets of such entries, that is, a set of entries whose array numbers are 0, 1 and 5 respectively, a set of entries whose array numbers are 3 and 6 respectively, and a set of entries whose array numbers are 4 and 9 as shown in FIG. 27 (C). As a result, the number of current threads can be presumed to be three. So, the CPU 30 determines that the current access pattern is multi-thread access (small).

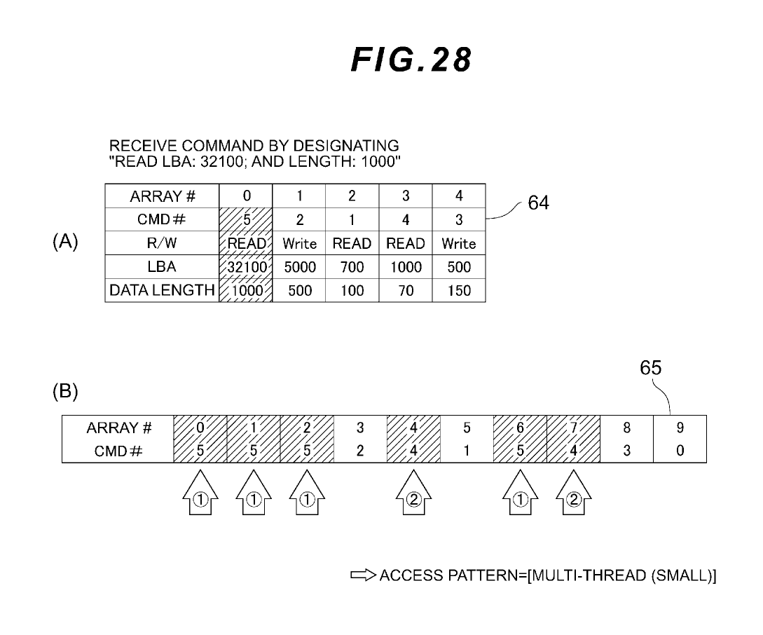

Subsequently, for example, FIGS. 28 to 31 show the state of the thread management basic table 64 and the latest received command management table 65 in cases where a first command in response to a read command, which specifies 32100 as the top block LBA of the read/write position and 1000 as the data length of the read target data, a first command in response to a read command, which specifies 33100 as the top block LBA of the read position and 1000 as the data length of the read target data, a first command in response to a read command, which specifies 34100 as the top block LBA of the read position and 1000 as the data length of the read target data, and a first command in response to a read command, which specifies 35100 as the top block LBA of the read position and 1000 as the data length of the read target data, are sequentially provided to the conversion chip 61.

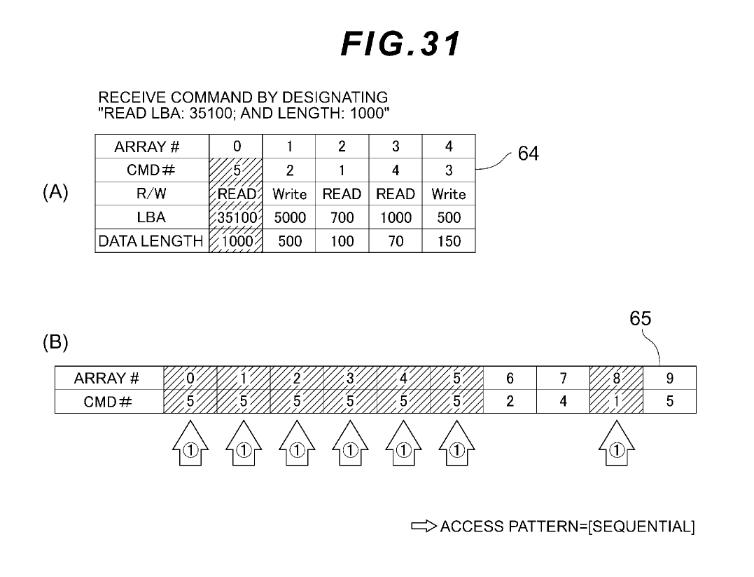

In the state shown in Figs. from 28 to 30, the CPU 30 determines that the current access pattern is multi-thread access (small), while in the state shown in of FIGS. 31 the CPU 30 determines that the current access pattern is sequential

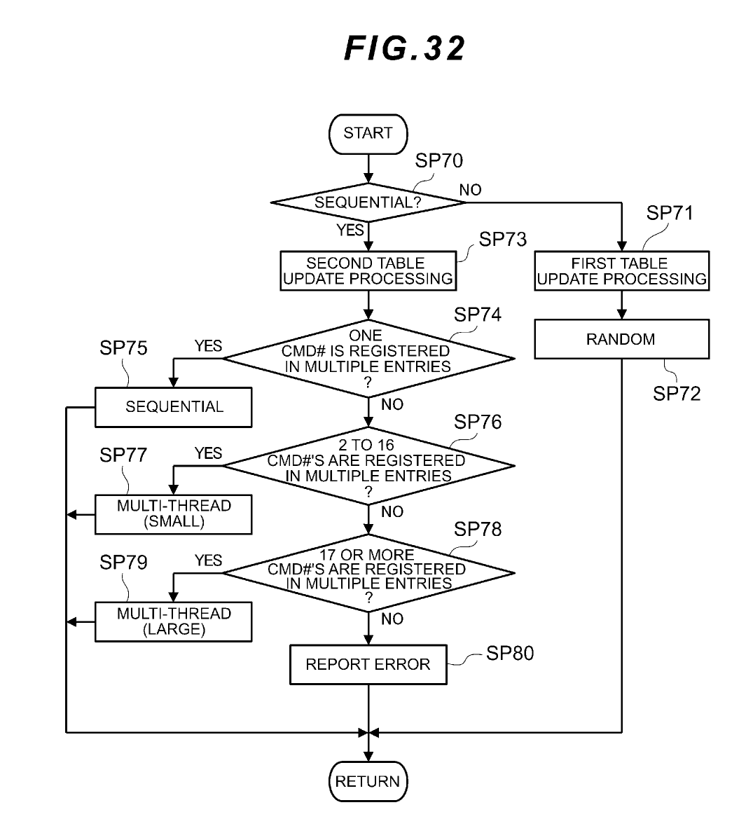

FIG. 32 shows the specific content for processing executed by the CPU 30 for the conversion chip 61 in relation to the above-mentioned access pattern judgment processing. When the CPU 30 proceeds to step SP62 in the fourth response time control processing (FIG. 15), it starts the access pattern judgment processing shown in FIG. 32, that is, firstly refers to the thread management basic table 64 and judges whether a received command, which specifies a storage area as a read/write position sequential to the read/write position specified by the currently received command and whose command type is the same, exists in the past received commands registered in the relevant thread management basic table 64 or not (SP70).

If a negative judgment is returned in this step (in the cases of, for example, FIG. 21, FIG. 22, and FIG. 25), the CPU 30 executes first table update processing described below (SP71).

Specifically speaking, the CPU 30 shifts each entry in the thread management basic table 64 to a row whose array number is larger by 1; and at the same time, if an entry which is pushed out of the thread management basic table 64 exists at that time, the CPU 30 creates entry information 64X corresponding to the currently received command by using the command number of that command, and adds this entry information 64X to the row whose array number is 0.

Furthermore, the CPU 30 shifts each respective entry of the latest received command management table 65, and stores the command number assigned to the currently received command to the command number field 65B in the row whose array number is 0 in the relevant latest received command management table 65. In addition, if an entry pushed out of the thread management basic table 64 as described above exists, the CPU 30 updates (clears) the command number stored in the command number field 65B of the row in the latest received command management table 65 corresponding to that entry to 0.

Then, after terminating the above-mentioned first table update processing, the CPU 30 determines that the current access pattern is random (SP72), then terminates this access pattern judgment processing, and returns to the fourth response time control processing (FIG. 15).

Meanwhile, if an affirmative judgment is returned in step SP70 (in cases of, for example, FIG. 23, FIG. 24, and FIG. 26), the CPU 30 executes second table update processing described below (SP73).

Specifically speaking, the CPU 30 creates entry information 64X by replacing the LBA field 64D and the data length field 64E of the entry corresponding to the received command which is determined to be the received command specifying a storage area, as a read/write position, which is sequential to the read position specified by the currently received command in the thread management basic table 64 with the information of the currently received command, and adds this entry information 64X to the row whose array number is 0 in the thread management basic table 64.

Furthermore, the CPU 30 shifts each entry of the latest received command management table 65, and stores the command number assigned to the currently received command to the command number field 65B in the row whose array number is 0 in the relevant latest received command management table 65. In addition, if an entry pushed out of the thread management basic table 64 as described above exists, the CPU 30 updates (clears) the command number stored in the command number field 65B of the row in the latest received command management table 65 corresponding to that entry to 0.

Furthermore, the CPU 30 shifts each entry of the latest received command management table 65, and stores the command number assigned to the currently received command to the command number field 65B in the row whose array number is 0 in the relevant latest received command management table 65.

Next, the CPU 30 judges whether the number of sets of entries whose command numbers are the same in the latest received command management table 65 is 1 or not (SP74). Then, if an affirmative judgment is returned, the CPU 30 determines that the current access pattern is sequential (SP75), then terminates this access pattern judgment processing, and returns to the fourth response time control processing.

Furthermore, if a negative judgment is returned in step SP74, the CPU 30 judges whether the number of sets of entries whose command numbers are the same in the latest received command management table 65 is within the range from 2 to 17 or not (SP76). Then, if an affirmative judgment is returned, the CPU 30 determines that the current access pattern is the multi-thread access (small) (SP77), then terminates this access pattern judgment processing, and returns to the fourth response time control processing.

Furthermore, if a negative judgment is returned in step SP76, the CPU 30 judges whether the number of sets of entries whose command numbers are the same in the latest received command management table 65 is within the range from 17 to 256 or not (SP78). Then, if an affirmative judgment is returned, the CPU 30 determines that the current access pattern is the multi-thread access (large) (SP79), then terminates this access pattern judgment processing, and returns to the fourth response time control processing.

Meanwhile, if a negative judgment is returned in step SP78, the CPU 30 transmits an alert to report that the access pattern cannot be determined, to the storage device communication control unit 16A, 16B for the controller 5A, 5B, then terminates this access pattern judgment processing, and returns to the fourth response time control processing.

(4-3) Advantageous Effects of This Embodiment

With the computer system 60 of this embodiment as described above, the wait time T_{W} of the response time control processing executed by the conversion chip 61 can be set minutely in accordance with the access pattern from the host computer 2A, 2B and the command content of the command received at that time. So, the response performance of the existing storage devices 4 and the new storage devices 4 as recognized by the controllers 5A, 5B can be substantially equalized more accurately.

Accordingly, it is possible to effectively prevent the resources from being occupied due to accumulation of commands only in command queues corresponding to part of the storage devices 4 constituting the same ECC group and realize a computer system capable of effectively preventing degradation of the response performance of the entire system

(5) Embodiment 5

Referring to FIG. 1, the reference numeral 70 represents the entire computer system according to this embodiment. This computer system 70 is configured in the same manner as the computer system 60 (FIG. 1) by Embodiment 3, except that the system administrator can set desired average response time for the conversion chip 71 (FIG. 1) as average response time T_{A} to be used for the response time control processing.

Practically, in the case of this computer system 70, the system administrator can specify a desired time (hereinafter referred to as the specified average response time) as the above-mentioned average response time T_{A} for the storage apparatus 3 by operating the management terminal 6 for the storage apparatus 3. Then, this specified average response time is reported to the microprocessors 15A, 15B (FIG. 1) for the 0-system and 1-system controllers 5A, 5B respectively and is provided to each conversion chip 71 via the storage device communication control units 16A, 16B under control of the relevant microprocessors 15A, 15B.

If such specified average response time is provided from the controller 5A, 5B, the CPU 30 stores this specified average response time in the memory 31 (FIG. 3) and then executes the response time control processing by using the specified average response time.

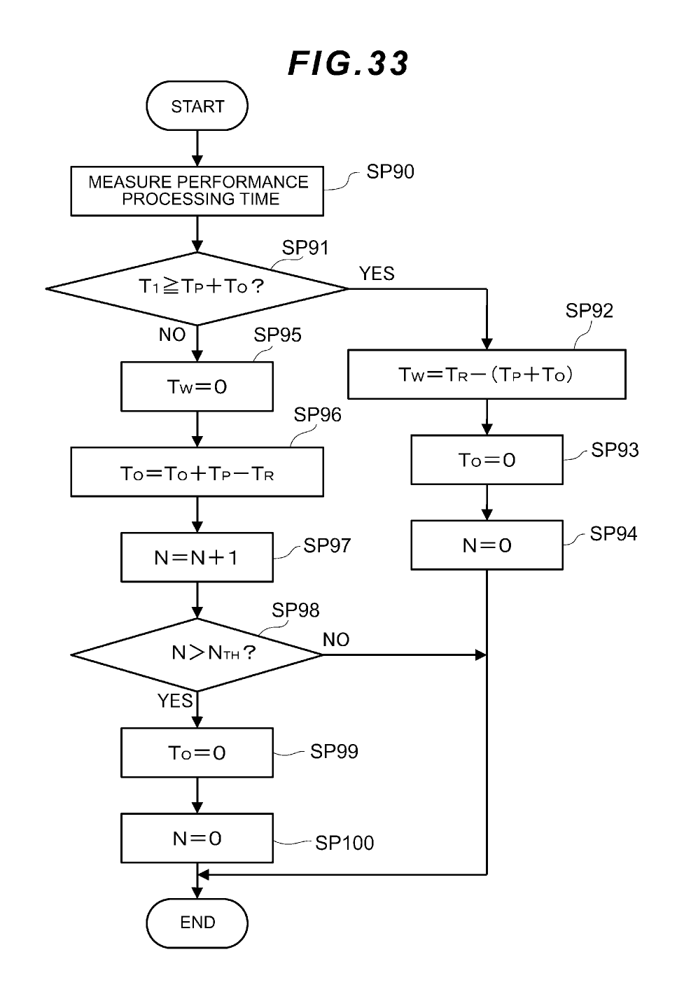

FIG. 33 shows the specific content of the processing by the CPU 30 for the conversion chip 71 in relation to the response time control processing according to the above-mentioned embodiment (hereinafter referred to as fifth response time control processing).

In this case, after receiving a first command from the storage device communication control unit 16A, 16B for the controller 5A, 5B, the CPU 30 starts this fifth response time control processing, that is, firstly measures a period of time from transmission of a second command in accordance with the first command to a new corresponding storage device 4 to the reception of a command termination report for the relevant second command (hereinafter referred to as the processing execution time) (SP90).

Subsequently, the CPU 30 recognizes specified average response time specified by the system administrator as described above as T_{R1}, processing execution time obtained by such measurement as T_{P}, and carried-over time as T_{D}, and judges whether the following math is satisfied or not (SP91).

[Math.6]

T_{R1}T_{P}+T_{D} (6)

Then, if a negative judgment is returned in this step, the CPU 30 proceeds to step SP92; and after executing processing in steps from SP92 to SP94 in the same manner as steps from SP48 to SP50 in the third response time control processing described above with reference to FIG. 10, the CPU 30 terminates this fifth response time control processing.

On the other hand, if an affirmative judgment is returned in step SP91, the CPU 30 proceeds to step SP95; and after executing processing in steps from SP95 to SP100 in the same manner as steps from SP42 to SP47 in the third response time control processing, the CPU 30 terminates this fifth response time control processing.

With the computer system 70 according to this embodiment as described above, the average response time T_{A} can be minutely set for each ECC group. So, the response performance of the existing storage devices 4 and the new storage devices 4 as recognized by the controllers 5A, 5B can be substantially equalized more accurately.

Accordingly, it is possible to effectively prevent the resources from being occupied due to accumulation of commands only in command queues corresponding to part of the storage devices 4 constituting the same ECC group and realize a computer system capable of effectively preventing degradation of the response performance of the entire system

(6) Embodiment 6

Referring to FIG. 1, the reference numeral 80 represents the entire computer system according to this embodiment. This computer system 80 is configured in the same manner as the computer system 60 (FIG. 1) by Embodiment 3, except that a sixth response time control function that is a combination of the third response time control function described earlier with reference to FIG. 10 and the fifth response time control function described above with reference to FIG. 33 is installed.

Practically, in the case of this computer system 80, the system administrator can set desired specified average response time for the conversion chip 81 (FIG. 1) in the storage apparatus 3 by operating the management terminal 6 of the storage apparatus 3 in the same manner as in the case of the computer system 70 according to Embodiment 5. If such specified average response time is set as the average response time T_{A}, the CPU 30 for the conversion chip 81 then executes the response time control processing by using the specified average response time.

On the other hand, if no such specified average response time is set as the average response time T_{A}, the CPU 30 for the conversion chip 81 executes the response time control processing by using previously registered average response time T_{A}.

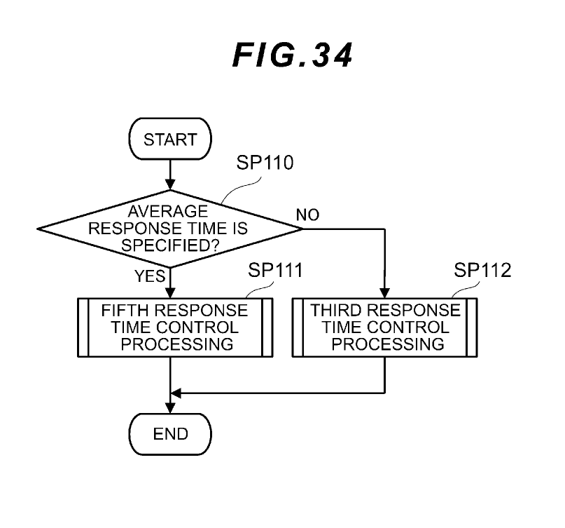

FIG. 34 shows the specific content of the processing executed by the CPU 30 for the conversion chip 81 in relation to the response time control processing according to the above-mentioned embodiment (hereinafter referred to as sixth response time control processing).

In this case, after receiving a first command from the storage device communication control unit 16A, 16B for the controller 5A, 5B, the CPU 30 starts this sixth response time control processing, that is, firstly judges whether the above-mentioned specified average response time is set as the average response time T_{A} or not (SP110).

Then, if an affirmative judgment is returned, the CPU 30 executes the fifth response time control processing described above with reference to FIG. 33 and then terminates this sixth response time control processing.

Meanwhile, if a negative judgment is returned in step SP110, the CPU 30 executes the third response time control processing described above with reference to FIG. 10 and then terminates this sixth response time control processing.

With the computer system 80 according to this embodiment as described above, the content of the response time control processing is switched to the third or fifth response time control processing depending on whether the specified average response time is set as the average response time T_{A} or not. So, in addition to the advantageous effects which can be obtained by the third and fifth embodiments, it is also possible to obtain the advantageous effect of the ability to execute the response time control processing in a manner that satisfies the demands of the system administrator better.

(7) Other Embodiments

Embodiments 1 to 6 described the cases where the function as the response time control unit which delays a response from the corresponding storage devices 4 to a command issued from the controller 5A, 5B and transfers the response to the controller is installed in the conversion chip 8 in which the protocol conversion function is installed in order to equalize the response time of a plurality of storage devices 4 constituting the same ECC group for the command issued from the controller 5A, 5B. However, the present invention is not limited to these examples, and such function as the response time control unit may be installed in an electronic component other than the conversion chip 8 and be attached to, and integrated with, a new storage device 4.

Furthermore, Embodiment 4 described the case where the average response time T_{A} is switched in accordance with the access pattern, the data length of the read/write target data, and the command type. However, this invention is not limited to this example, and the average response time T_{A} may also be switched in accordance with other factors than those listed above.

Furthermore, Embodiment 5 described the case where the system administrator can specify the average response time T_{A} data. However, this invention is not limited to this example, and, for example, the controller 5A, 5B may be designed to be capable of specifying the average response time T_{A} in accordance with the processing status of the respective storage devices 4.

Furthermore, the system administrator or the controller 5A, 5B may specify the wait time T_{W} instead of or in addition to the average response time T_{A} and the conversion chip 8, 41, 51, 61, 71, 81 may execute the response time control processing by using the specified wait time T_{W}. It is possible to obtain the same advantageous effects as those in Embodiments 1 to 6 by, for example, allowing the controller 5A, 5B to specify the wait time T_{W} in accordance with the processing status of the respective storage devices 4.

Furthermore, Embodiment 6 described the case where the response time control processing according to Embodiment 3 and the response time control processing according to Embodiment 5 are combined. However, this invention is not limited to this example, and the various types of response time control processing according to Embodiments 1 to 6 may also be combined as necessary.

### INDUSTRIAL APPLICABILITY

This invention can be broadly applied to various types of storage apparatuses in which a plurality of storage devices are installed.

### REFERENCE SIGNS LIST

1, 40, 50, 60, 70, 80 Computer system

2A, 2B Host computer

3 Storage apparatus

4 Storage device

5A, 5B Controller

8, 41, 51, 61, 71, 81 Conversion chip

16A, 16B Storage device communication control unit

30 CPU

31 Memory

62 Read response time management table

63 Write response time management table

64 Thread management basic table

65 Latest received command management table

T_{A} Average response time

T_{D} Carried time

T_{O}, T_{N} Processing time

T_{W} Wait time

1. A storage apparatus comprising:
a plurality of storage devices;
a controller for controlling data input to, and/or output from, the plurality of storage devices; and
a response time control unit located between the controller and part of or all the storage devices, for delaying a response of a corresponding storage device to a command issued from the controller and transferring the response to the controller to equalize response time for the plurality of storage devices to respond to the command.

2. The storage apparatus according to claim 1, wherein the response time control unit transfers the command issued from the controller to the corresponding storage device in accordance with a communication protocol, to which the corresponding storage device conforms, and transfers the response to the command, which is sent from the storage device, to the controller in accordance with a communication protocol to which the controller conforms.

3. The storage apparatus according to claim 1, wherein the plurality of storage devices constitute the same ECC (Error Check and Correction) group.

4. The storage apparatus according to claim 1, wherein the response time control unit delays the response of the corresponding storage device to the command from the controller for only a specified fixed time period and transfers the response to the controller.

5. The storage apparatus according to claim 1, wherein the response time control unit is located between some storage devices, whose response performance is higher than others storage devices from among the plurality of storage devices, and the controller; and
the response time control unit delays the response of the corresponding storage device to the command from the controller for a time difference between average response time of the other storage devices to the command and actual response time of the corresponding storage device to the command and transfers the response to the controller.

6. The storage apparatus according to claim 5, wherein when the timing of processing termination by the corresponding storage device with respect to the command is later than the target timing of processing termination based on the average response time, the response time control unit transfers, to the controller, the response of the corresponding storage device to the command from the controller without delaying it.

7. The storage apparatus according to claim 5, wherein the response time control unit:
judges a current access pattern based on a plurality of commands issued from the controller; and
sets time as the average response time according to the current access pattern judged above, data length of read or write target data, and a command type.

8. A response time control method for a storage apparatus having a plurality of storage devices and a controller for controlling data input to, and/or output from, the plurality of storage devices, the storage apparatus including a response time control unit located between the controller and part of or all the storage devices, and the response time control method comprising:
a first step executed by the response time control unit of transferring a command issued from the controller to a corresponding storage device; and
a second step executed by the response time control unit of delaying a response of the corresponding storage device to the command and transferring it to the controller in order to equalize response time for the plurality of storage devices to respond to the command.

9. The response time control method according to claim 8, wherein in the first step, the response time control unit transfers the command issued from the controller to the corresponding storage device in accordance with a communication protocol, to which the corresponding storage device conforms; and
wherein in the second step, the response time control unit transfers the response to the command, which is sent from the storage device, to the controller in accordance with a communication protocol to which the controller conforms.

10. The response time control method according to claim 8, wherein the plurality of storage devices constitute the same ECC (Error Check and Correction) group.

11. The response time control method according to claim 8, wherein in the second step, the response time control unit delays the response of the corresponding storage device to the command from the controller for only a specified fixed time period and transfers the response to the controller.

12. The response time control method according to claim 8, wherein the response time control unit is located between some storage devices, whose response performance is higher than others storage devices from among the plurality of storage devices, and the controller; and
wherein in the second step, the response time control unit delays the response of the corresponding storage device to the command from the controller for a time difference between average response time of the other storage devices to the command and actual response time of the corresponding storage device to the command and transfers the response to the controller.

13. The response time control method according to claim 12, wherein when in the second step the timing of processing termination by the corresponding storage device with respect to the command is later than the target timing of processing termination based on the average response time, the response time control unit transfers, to the controller, the response of the corresponding storage device to the command from the controller without delaying it.

14. The response time control method according to claim 12, wherein in the second step, the response time control unit:
judges a current access pattern based on a plurality of commands issued from the controller; and
sets time as the average response time according to the current access pattern judged above, data length of read or write target data, and a command type.
